(19) United States
(12) Patent Application Publication
(10) Pub. No.: US 2026/0006991 A1
(43) Pub. Date: Jan. 1, 2026

(54) DISPLAY DEVICE AND ELECTRONIC DEVICE INCLUDING THE SAME

(71) Applicant: Samsung Display Co., Ltd., Yongin-si (KR)

(72) Inventors: SOOHONG CHEON, Yongin-si (KR); KYUNG-HO PARK, Yongin-si (KR); HYUNGJIN SONG, Yongin-si (KR)

(21) Appl. No.: 19/090,223

(22) Filed: Mar. 25, 2025

(30) Foreign Application Priority Data
Jun. 27, 2024 (KR) 10-2024-0084546
Oct. 18, 2024 (KR) 10-2024-0142945

(51) Int. Cl. H10K 59/121; H10K 59/131

(52) U.S. Cl. CPC H10K 59/1213; H10K 59/1216; H10K 59/131

(57) ABSTRACT

A display device includes: a first light emitting element, a second light emitting element spaced from the first light emitting element in a plan view, a first pixel driving circuit portion including a driving transistor electrically connected to the first light emitting element, wherein the driving transistor in the first pixel driving circuit portion at least partially overlaps the first light emitting element in a plan view, and a second pixel driving circuit portion including a driving transistor electrically connected to the second light emitting element, wherein the driving transistor in the second pixel driving circuit portion at least partially overlaps the first light emitting element in a plan view.

### CROSS-REFERENCE TO RELATED APPLICATION(S)

The present application claims priority to and the benefit of Korean Patent Application No. 10-2024-0084546, filed on Jun. 27, 2024, and Korean Patent Application No. 10-2024-0142945, filed on Oct. 18, 2024, in the Korean Intellectual Property Office, the entire disclosures of all of which are incorporated by reference herein.

### BACKGROUND

### 1. Field

The present disclosure relates to a display device and an electronic device including the display device. More particularly, the present disclosure relates to a display device providing visual information and an electronic device including the display device.

### 2. Description of the Related Art

A display device is a device that displays an image for providing visual information to a user. Among display devices, an organic light emitting diode (OLED) display device has recently attracted attention.

The organic light emitting diode display device may include a light emitting element and a pixel driving circuit portion electrically connected to the light emitting element. As the light emitting element emits light in all directions, light emitted from the light emitting element may reach a transistor included in the pixel driving circuit portion.

### SUMMARY

Embodiments of the present disclosure provide a display device with improved quality.

Embodiments of the present disclosure provide an electronic device including the display device.

A display device according to one or more embodiments includes a first light emitting element, a second light emitting element spaced from the first light emitting element in a plan view, a first pixel driving circuit portion including a driving transistor electrically connected to the first light emitting element, wherein the driving transistor in the first pixel driving circuit portion at least partially overlaps the first light emitting element in a plan view, and a second pixel driving circuit portion including a driving transistor electrically connected to the second light emitting element, wherein the driving transistor in the second pixel driving circuit portion at least partially overlaps the first light emitting element in a plan view.

In one or more embodiments, the driving transistor in the first pixel driving circuit portion may be configured to provide a driving current to the first light emitting element.

In one or more embodiments, the driving transistor in the second pixel driving circuit portion may be configured to provide a driving current to the second light emitting element.

In one or more embodiments, the display device may further include a voltage line electrically connected to each of the first pixel driving circuit portion and the second pixel driving circuit portion.

In one or more embodiments, the driving transistor in the first pixel driving circuit portion may be located at one side of the voltage line.

In one or more embodiments, the driving transistor in the second pixel driving circuit portion may be located at other side of the voltage line.

In one or more embodiments, each of the first pixel driving circuit portion and the second pixel driving circuit portion may further include a capacitor.

In one or more embodiments, the capacitor in the first pixel driving circuit portion may be located at one side of the voltage line.

In one or more embodiments, the capacitor in the second pixel driving circuit portion may be located at an other side of the voltage line.

In one or more embodiments, the voltage line may be configured to apply a power voltage to each of the first pixel driving circuit portion and the second pixel driving circuit portion.

In one or more embodiments, each of the first pixel driving circuit portion and the second pixel driving circuit portion may further include a first switching transistor.

In one or more embodiments, the first switching transistor in the first pixel driving circuit portion may be located at one side of the voltage line.

In one or more embodiments, the first switching transistor in the second pixel driving circuit portion may be located at an other side of the voltage line.

In one or more embodiments, each of the first pixel driving circuit portion and the second pixel driving circuit portion further may include a second switching transistor.

In one or more embodiments, each of the second switching transistor in the first pixel driving circuit portion and the second switching transistor in the second pixel driving circuit portion may be located at the one side of the voltage line or the other side of the voltage line.

In one or more embodiments, the display device may further include a third light emitting element spaced from each of the first light emitting element and the second light emitting element in a plan view and a third pixel driving circuit portion including a driving transistor electrically connected to the third light emitting element.

In one or more embodiments, the driving transistor in the third pixel driving circuit portion may at least partially overlap the third light emitting element in a plan view.

In one or more embodiments, the first light emitting element, the second light emitting element, and the third light emitting element may be configured to emit light having different wavelengths from each other.

In one or more embodiments, the display device may further include a voltage line electrically connected to each of the first pixel driving circuit portion, the second pixel driving circuit portion, and the third pixel driving circuit portion.

In one or more embodiments, each of the driving transistor in the first pixel driving circuit portion and the driving transistor in the third pixel driving circuit portion may be located at one side of the voltage line.

In one or more embodiments, the driving transistor in the second pixel driving circuit portion may be located at an other side of the voltage line.

In one or more embodiments, each of the first pixel driving circuit portion, the second pixel driving circuit portion, and the third pixel driving circuit portion may further include a capacitor.

In one or more embodiments, each of the capacitor in the first pixel driving circuit portion and the capacitor in the third pixel driving circuit portion may be located at one side of the voltage line.

In one or more embodiments, the capacitor in the second pixel driving circuit portion may be located at an other side of the voltage line.

A display device according to one or more embodiments of the present disclosure includes a first light emitting element, a second light emitting element spaced from the first light emitting element in a plan view, a voltage line, a first pixel driving circuit portion including a driving transistor located at one side of the voltage line, wherein the first pixel driving circuit portion is electrically connected to each of the first light emitting element and the voltage line, and a second pixel driving circuit portion including a driving transistor located at an other side of the voltage line, wherein the second pixel driving circuit portion is electrically connected to each of the second light emitting element and the voltage line.

In one or more embodiments, the driving transistor in the first pixel driving circuit portion may at least partially overlaps the first light emitting element in a plan view.

In one or more embodiments, the driving transistor in the second pixel driving circuit portion may at least partially overlaps the second light emitting element in a plan view.

In one or more embodiments, the voltage line may be configured to apply a power voltage to each of the first pixel driving circuit portion and the second pixel driving circuit portion.

In one or more embodiments, each of the first pixel driving circuit portion and the second pixel driving circuit portion may further include a capacitor.

In one or more embodiments, the capacitor in the first pixel driving circuit portion may be located at the one side of the voltage line.

In one or more embodiments, the capacitor in the second pixel driving circuit portion may be located at the other side of the voltage line.

In one or more embodiments, the display device may further include a third light emitting element spaced from each of the first light emitting element and the second light emitting element in a plan view and a third pixel driving circuit portion electrically connected to each of the third light emitting element and the voltage line.

In one or more embodiments, the third pixel driving circuit portion may include a driving transistor located at the one side of the voltage line or other side of the voltage line.

An electronic device according to one or more embodiments of the present disclosure includes a first light emitting element, a second light emitting element spaced from the first light emitting element in a plan view, a first pixel driving circuit portion including a driving transistor electrically connected to the first light emitting element, wherein the driving transistor in the first pixel driving circuit portion at least partially overlaps the first light emitting element in a plan view, a second pixel driving circuit portion including a driving transistor electrically connected to the second light emitting element, wherein the driving transistor in the second pixel driving circuit portion at least partially overlaps the first light emitting element in a plan view, and a memory configured to store data information.

A display device according to one or more embodiments of the present disclosure may include a first light emitting element, a second light emitting element spaced apart from the first light emitting element in a plan view, a first pixel driving circuit portion including a driving transistor electrically connected to the first light emitting element, and a second pixel driving circuit portion including a driving transistor electrically connected to the second light emitting element. The driving transistor in the first pixel driving circuit portion at least partially overlaps the first light emitting element in a plan view. The driving transistor in the second pixel driving circuit portion at least partially overlaps the first light emitting element in a plan view.

Accordingly, light emitted from the first light emitting element may be prevented from reaching the driving transistor in the second pixel driving circuit portion. In addition, light emitted from the second light emitting element may be prevented from reaching the driving transistor in the first pixel driving circuit portion. Accordingly, deterioration of the driving transistor in the first pixel driving circuit portion and the driving transistor in the second pixel driving circuit portion may be prevented.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to one or more embodiments.

FIG. 2 is a block diagram illustrating the display device of FIG. 1.

FIG. 3 is a circuit diagram illustrating a pixel.

FIGS. 4, 5, 6, 7, 8, 9, 10, 11, 12, and 13 are layout views illustrating pixels included in the display device of FIG. 1 according to one or more embodiments.

FIG. 14 is a cross-sectional view of the display device of FIG. 13 taken along the line I-I′ of FIG. 13.

FIGS. 15, 16, 17, 18, 19, 20, 21, 22, 23, and 24 are layout views illustrating pixels included in the display device of FIG. 1 according to one or more embodiments.

FIG. 25 is a block diagram of an electronic device according to one or more embodiments.

FIG. 26 is a schematic diagram of an electronic device according to various embodiments.

### DETAILED DESCRIPTION

Hereinafter, display devices in accordance with embodiments will be described in more detail with reference to the accompanying drawings. The same reference numerals are used for the same components in the drawings, and redundant descriptions of the same components will be omitted.

Aspects and features of embodiments of the present disclosure and methods of accomplishing the same may be understood more readily by reference to the detailed description of embodiments and the accompanying drawings. Hereinafter, aspects of some embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit and/or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and/or the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132 (a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

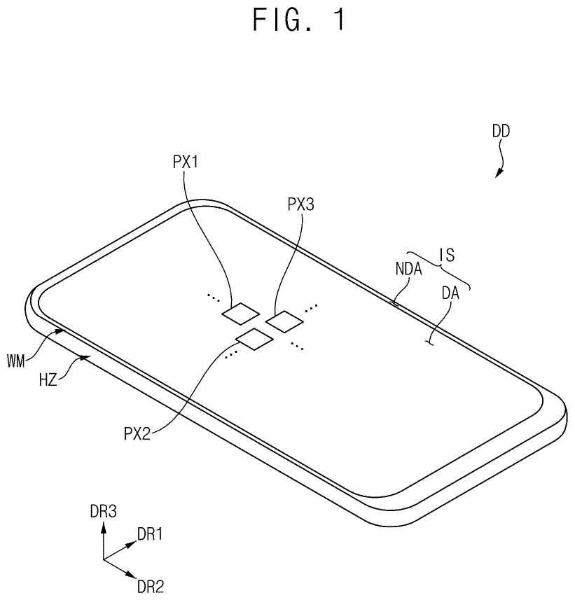

FIG. 1 is a plan view illustrating a display device according to one or more embodiments.

Referring to FIG. 1, a display device DD according to one or more embodiments may be a device activated by an electrical signal. For example, the display device DD may be a small display device used in small electronic device such as smartphone, mobile phone, smart watches, game console, cameras, and/or the like. However, the present disclosure is not limited thereto, and the display device DD may be a medium or large-sized display device used in a medium or large-sized electronic device such as a notebook, a tablet, a PC, a television, a computer monitor, a vehicle monitor, an external billboard, and/or the like.

An upper surface of the display device DD may be defined as a display surface IS. The display surface IS may be a surface parallel to a plane formed in a first direction DR1 and a second direction DR2 crossing the first direction DR1. An image generated by the display device DD may be provided to a user through the display surface IS.

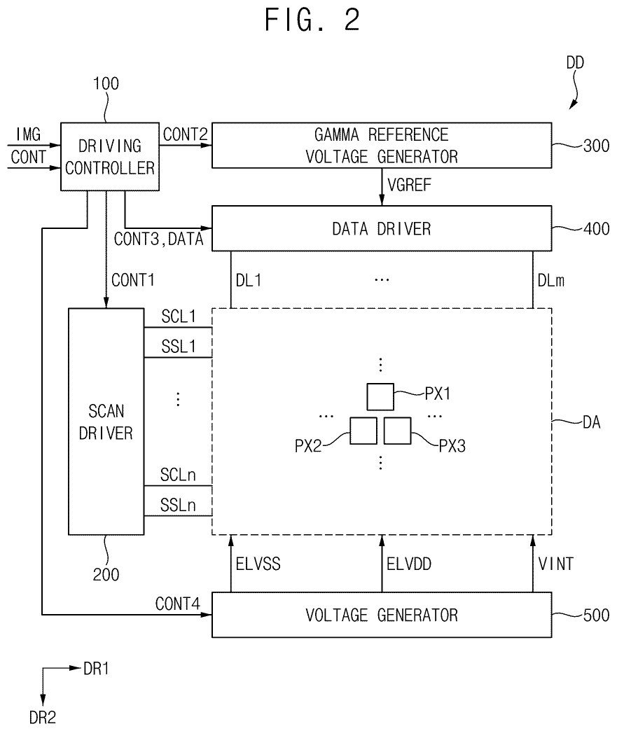

The display device DD may include a display area DA and a non-display area NDA. For example, the display surface IS may include the display area DA and the non-display area NDA. The display area DA may be an area in which an image is displayed. For example, the display area DA may be an area that generates light or adjusts transmittance of light provided from an external light source to display an image. The non-display area NDA may be around (e.g., may surround) at least a portion of the display area DA along an edge or a periphery of the display area DA. In one or more embodiments, the non-display area NDA may be an area in which an image is not displayed. However, the present disclosure is not limited thereto, and an image may be displayed in a portion of the non-display area NDA. The non-display area NDA may include a plurality of drivers. The plurality of drivers may be described later with reference to FIG. 2.

A plurality of pixels may be located in the display area DA. For example, a first pixel PX1, a second pixel PX2, and a third pixel PX3 may be located in the display area DA. Each of the first pixel PX1, the second pixel PX2, and the third pixel PX3 may emit light. In one or more embodiments, the first pixel PX1, the second pixel PX2, and the third pixel PX3 may emit light having different wavelengths to each other. For example, the first pixel PX1 may emit green light, the second pixel PX2 may emit red light, and the third pixel PX3 may emit blue light, but the present disclosure is not limited thereto. The first pixel PX1, the second pixel PX2, and the third pixel PX3 may be spaced (e.g., spaced apart) from each other in a plan view. The plurality of pixels may be overall located in the display area DA. Accordingly, the display area DA may display an image.

The display device DD may include a housing HZ and a window WM. The housing HZ and the window WM may be coupled to constitute an external appearance of the display device DD. The housing HZ may protect components included in the display device DD from external impact. The housing HZ may include a material having relatively high rigidity. For example, the housing HZ may include glass, plastic, metal, and/or the like. These materials may be used alone or in combination with each other. The window WM may be coupled to the housing HZ. For example, the window WM may be an ultra-thin glass and/or polyimide film, but the present disclosure is not limited thereto.

In one or more embodiments, the first direction DR1 and the second direction DR2 crossing the first direction DR1 may be defined. For example, the second direction DR2 may be substantially perpendicular to the first direction DR1. However, the present disclosure is not limited thereto, and the second direction DR2 may form an acute angle or an obtuse angle with the first direction DR1. In addition, a third direction DR3 crossing a plane formed by the first direction DR1 and the second direction DR2 may be defined. For example, the third direction DR3 may be substantially perpendicular to a plane formed by the first direction DR1 and the second directions DR2. However, the present disclosure is not limited thereto, and the third direction DR3 may form an acute angle or an obtuse angle with a plane formed by the first direction DR1 and the second direction DR2.

FIG. 2 is a block diagram illustrating the display device of FIG. 1.

Referring to FIG. 2, the display device DD may include a driving controller 100, a scan driver 200, a gamma reference voltage generator 300, a data driver 400, and a voltage generator 500. As described above, the non-display area (e.g., the non-display area NDA of FIG. 1) may include a plurality of drivers, and the plurality of drivers may include the driving controller 100, the scan driver 200, the gamma reference voltage generator 300, the data driver 400, and the voltage generator 500.

The driving controller 100 may receive input image data IMG and input control signal CONT from an external device. In one or more embodiments, the input image data IMG may include red image data, green image data, and blue image data. In one or more embodiments, the input image data IMG may include white image data. In one or more embodiments, the input image data IMG may include magenta image data, yellow image data, and/or cyan image data. The input control signal CONT may include a master clock signal and a data enable signal. The input control signal CONT may further include a vertical synchronization signal and a horizontal synchronization signal.

The driving controller 100 may generate a first control signal CONT1, a second control signal CONT2, a third control signal CONT3, a fourth control signal CONT4, and a data signal DATA based on the input image data IMG and the input control signal CONT. For example, the driving controller 100 may generate the first control signal CONT1 based on the input control signal CONT and output the first control signal CONT1 to the scan driver 200. The first control signal CONT1 may include a vertical start signal and a gate clock signal. In addition, the driving controller 100 may generate the second control signal CONT2 based on the input control signal CONT and output the second control signal CONT2 to the gamma reference voltage generator 300. In addition, the driving controller 100 may generate the third control signal CONT3 based on the input control signal CONT and output the third control signal CONT3 to the data driver 400. The third control signal CONT3 may include a horizontal start signal and a load signal. In addition, the driving controller 100 may generate the fourth control signal CONT4 based on the input control signal CONT and output the fourth control signal CONT4 to the voltage generator 500. In addition, the driving controller 100 may generate the data signal DATA based on the input image data IMG and output the data signal DATA to the data driver 400.

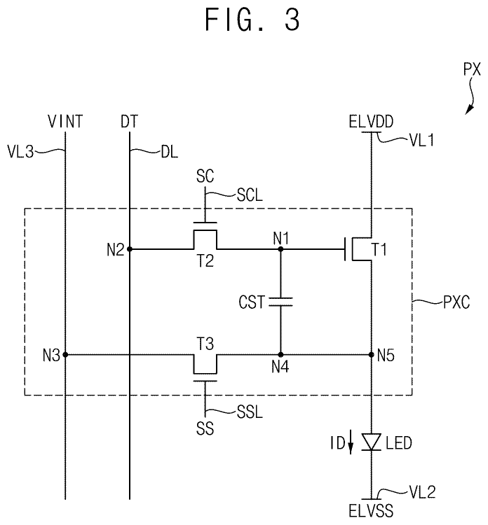

The scan driver 200 may output signals to signal lines in response to the first control signal CONT1. For example, the scan driver 200 may output signals to scan signal lines SCL1 to SCLn and sensing signal lines SSL1 to SSLn in response to the first control signal CONT1. For example, the scan driver 200 may output a scan signal (e.g., a scan signal SC of FIG. 3) to the scan signal lines SCL1 to SCLn and output a sensing signal (e.g., a sensing signal SS of FIG. 3) to the sensing signal lines SSL1 to SSLn.

The gamma reference voltage generator 300 may generate a gamma reference voltage VGREF in response to the second control signal CONT2. The gamma reference voltage generator 300 may provide the gamma reference voltage VGREF to the data driver 400. For example, the gamma reference voltage VGREF may have a value corresponding to the data signal DATA.

The data driver 400 may receive an input of the third control signal CONT3 and the data signal DATA from the driving controller 100. In addition, the data driver 400 may receive an input of the gamma reference voltage VGREF from the gamma reference voltage generator 300. The data driver 400 may convert the data signal DATA into an analog data voltage (for example, a data voltage DT of FIG. 3) using the gamma reference voltage VGREF. The data driver 400 may output the data voltage to data lines DL1 to DLm.

The voltage generator 500 may generate a first power voltage ELVDD, a second power voltage ELVSS, and an initialization voltage VINT in response to the fourth control signal CONT4. The voltage generator 500 may output the first power voltage ELVDD, the second power voltage ELVSS, and the initialization voltage VINT to the display area DA.

FIG. 2 may illustrate an example of positions of the plurality of drivers. For example, the scan driver 200 may be spaced (e.g., spaced apart) from the display area DA in a direction opposite to the first direction DR1, the gamma reference voltage generator 300 and the data driver 400 may be spaced (e.g., spaced apart) from the display area DA in a direction opposite to the second direction DR2, and the voltage generator 500 may be spaced (e.g., spaced apart) from the display area DA in the second direction DR2. However, the present disclosure is not limited thereto, and positions of the plurality of drivers may be variously changed according to embodiments.

The display area DA may be electrically connected to scan signal lines SCL1 to SCLn, sensing signal lines SSL1 to SSLn, and data lines DL1 to DLm. The first pixel PX1 may be connected to a corresponding scan signal line of the scan signal lines SCL1 to SCLn, a corresponding sensing signal line of the sensing signal lines SSL1 to SSLn, and a corresponding data line of the data lines DL1 to DLm. In addition, the second pixel PX2 may be connected to a corresponding scan signal line of the scan signal lines SCL1 to SCLn, a corresponding sensing signal line of the sensing signal lines SSL1 to SSLn, and a corresponding data line of the data lines DL1 to DLm. In addition, the third pixel PX3 may be connected to a corresponding scan signal line of the scan signal lines SCL1 to SCLn, a corresponding sensing signal line of the sensing signal lines SSL1 to SSLn, and a corresponding data line of the data lines DL1 to DLm.

In one or more embodiments, the scan signal lines SCL1 to SCLn may extend in the first direction DR1 and may be arranged along the second direction DR2. In addition, the sensing signal lines SSL1 to SSLn may extend in the first direction DR1 and may be arranged along the second direction DR2. In addition, the data lines DL1 to DLm may extend in the second direction DR2 and may be arranged along the first direction DR1. However, the present disclosure is not limited thereto, and an extension direction and an arrangement direction of the scan signal lines SCL1 to SCLn, the sensing signal lines SSL1 to SSLn, and the data lines DL1 to DLm may be variously changed according to embodiments.

FIG. 3 is a circuit diagram illustrating a pixel.

Specifically, FIG. 3 is a circuit diagram illustrating a first pixel PX1, a second pixel PX2, and a third pixel PX3 included in the display device DD of FIG. 2. For example, each of the first pixel PX1, the second pixel PX2, and the third pixel PX3 of FIG. 2 may have a circuit diagram illustrated in FIG. 3.

Referring to FIG. 3, the pixel PX may include a light emitting element LED and a pixel driving circuit portion PXC electrically connected to the light emitting element LED. The pixel driving circuit portion PXC may include a first transistor T1, a second transistor T2, a third transistor T3, and a capacitor CST.

In one or more embodiments, each of the first transistor T1, the second transistor T2, and the third transistor T3 may be an n-type transistor. An active pattern of the n-type transistor may include an oxide semiconductor material. However, the present disclosure is not limited thereto, and the active pattern of the n-type transistor may include a silicon semiconductor material.

In one or more embodiments, each of the first transistor T1, the second transistor T2, and the third transistor T3 may be a p-type transistor. In one or more embodiments, some of the first transistor T1, the second transistor T2, and the third transistor T3 may be n-type transistor, and others may be p-type transistor. An active pattern of the p-type transistor may include a silicon semiconductor material.

The pixel driving circuit portion PXC may be electrically connected to a first voltage line VL1, a second voltage line VL2, a third voltage line VL3, a scan signal line SCL, a sensing signal line SSL, and a data line DL.

The first voltage line VL1 may apply a first power voltage ELVDD to the pixel driving circuit portion PXC. The second voltage line VL2 may apply a second power voltage ELVSS to the pixel driving circuit portion PXC. In one or more embodiments, voltage level of the first power voltage ELVDD may be higher than voltage level of the second power voltage ELVSS. The third voltage line VL3 may apply an initialization voltage VINT to the pixel driving circuit portion PXC. The scan signal line SCL may apply a scan signal SC to the pixel driving circuit portion PXC. The sensing signal line SSL may apply a sensing signal SS to the pixel driving circuit portion PXC.

The first transistor T1 may include a gate terminal, a first terminal, and a second terminal. The gate terminal of the first transistor T1 may be connected to a first node N1. The first terminal of the first transistor T1 may be connected to the first voltage line VL1. The second terminal of the first transistor T1 may be connected to a fifth node N5. The first transistor T1 may provide a driving current ID to the light emitting element LED. For example, the first transistor T1 may be referred to as a driving transistor.

The second transistor T2 may include a gate terminal, a first terminal, and a second terminal. The gate terminal of the second transistor T2 may be connected to the scan signal line SCL. The first terminal of the second transistor T2 may be connected to a second node N2. The second terminal of the second transistor T2 may be connected to the first node N1.

The gate terminal of the second transistor T2 may receive the scan signal SC through the scan signal line SCL. The second transistor T2 may be turned on or off in response to the scan signal SC. For example, when the second transistor T2 is an n-type transistor, the second transistor T2 may be turned off when the scan signal SC has a negative voltage level, and may be turned on when the scan signal SC has a positive voltage level. In addition, when the second transistor T2 is a p-type transistor, the second transistor T2 may be turned off when the scan signal SC has a positive voltage level, and may be turned on when the scan signal SC has a negative voltage level. The first terminal of the second transistor T2 may receive the data voltage DT through the data line DL. For example, the first terminal of the second transistor T2 may receive the data voltage DT through the second node N2. The second terminal of the second transistor T2 may provide the data voltage DT to the first node N1 during a period in which the second transistor T2 is turned on. Accordingly, the second transistor T2 may drive the first transistor T1. For example, the second transistor T2 may be referred to as a first switching transistor.

The third transistor T3 may include a gate terminal, a first terminal, and a second terminal. The gate terminal of the third transistor T3 may be connected to the sensing signal line SSL. The first terminal of the third transistor T3 may be connected to a third node N3. The second terminal of the third transistor T3 may be connected to a fourth node N4.

The gate terminal of the third transistor T3 may receive the sensing signal SS through the sensing signal line SSL. The third transistor T3 may be turned on or off in response to the sensing signal SS. For example, when the third transistor T3 is an n-type transistor, the third transistor T3 may be turned off when the sensing signal SS has a negative voltage level, and may be turned on when the sensing signal SS has a positive voltage level. In addition, when the third transistor T3 is a p-type transistor, the third transistor T3 may be turned off when the sensing signal SS has a positive voltage level, and may be turned on when the sensing signal SS has a negative voltage level. The third transistor T3 may receive the initialization voltage VINT through the third voltage line VL3. For example, the third transistor T3 may receive the initialization voltage VINT through the third node N3. During a period in which the third transistor T3 is turned on, the third transistor T3 may provide the initialization voltage VINT to the fifth node N5. Accordingly, the third transistor T3 may initialize a first electrode of the light emitting element LED. For example, the third transistor T3 may be referred to as a second switching transistor.

The capacitor CST may include a first terminal and a second terminal. The first terminal of the capacitor CST may be connected to the first node N1. The second terminal of the capacitor CST may be connected to the fourth node N4. A charge corresponding to a difference between voltage of the gate terminal of the first transistor T1 and voltage of the second terminal of the first transistor T1 may be stored in the capacitor CST.

The light emitting element LED may include a first terminal and a second terminal. The first terminal of the light emitting element LED may be connected to the fifth node N5. The second terminal of the light emitting element LED may be connected to the second voltage line VL2. For example, the first terminal of the light emitting element LED may be an anode terminal, and the second terminal of the light emitting element LED may be a cathode terminal.

As illustrated in FIG. 3, the pixel driving circuit portion PXC may include three transistors and one capacitor. However, the present disclosure is not limited thereto, and number of transistors and capacitors included in the pixel driving circuit portion PXC may be variously changed according to embodiments.

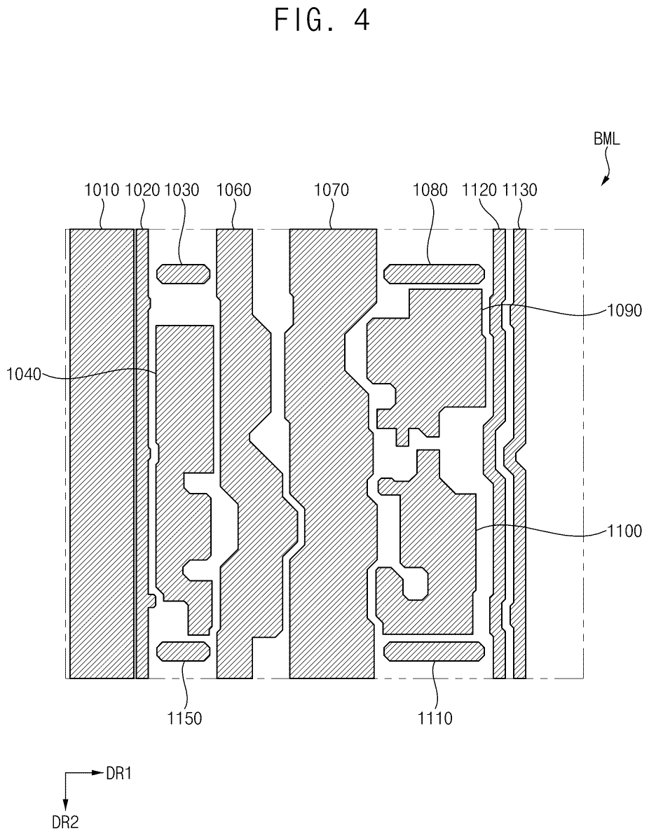

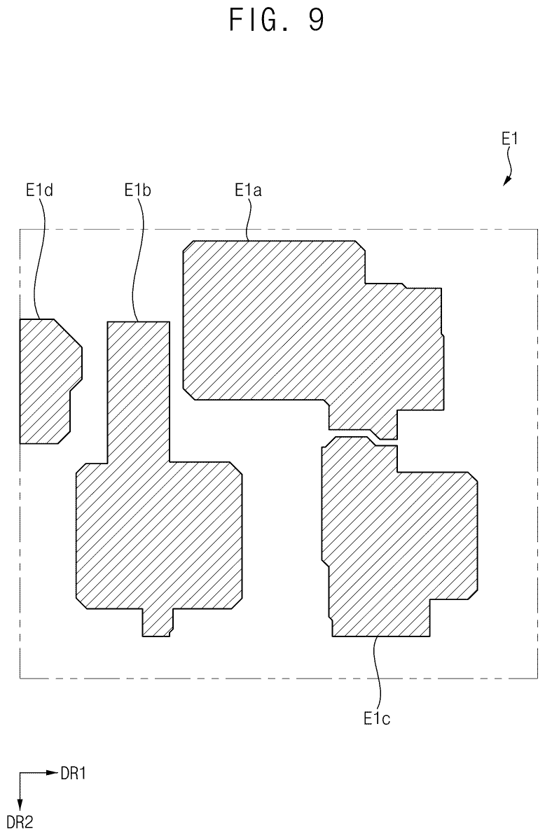

FIGS. 4, 5, 6, 7, 8, 9, 10, 11, 12, and 13 are layout views illustrating pixels included in the display device of FIG. 1 according to one or more embodiments.

Specifically, FIGS. 4, 5, 6, 7, 8, 9, 10, 11, 12, and 13 may be arrangement views illustrating the first pixel PX1, the second pixel PX2, and the third pixel PX3 of FIG. 2.

Referring to FIG. 4, a display device (for example, the display device DD of FIG. 2) may include a lower metal layer BML. The lower metal layer BML may include a first lower metal pattern 1010, a second lower metal pattern 1020, a third lower metal pattern 1030, a fourth lower metal pattern 1040, a fifth lower metal pattern 1050, a sixth lower metal pattern 1060, a seventh lower metal pattern 1070, an eighth lower metal pattern 1080, a ninth lower metal pattern 1090, a tenth lower metal pattern 1100, an eleventh lower metal pattern 1110, a twelfth lower metal pattern 1120, and a thirteenth lower metal pattern 1130.

The first lower metal pattern 1010, the second lower metal pattern 1020, the third lower metal pattern 1030, the fourth lower metal pattern 1040, the fifth lower metal pattern 1050, the sixth lower metal pattern 1060, the seventh lower metal pattern 1070, the eighth lower metal pattern 1080, the ninth lower metal pattern 1090, the tenth lower metal pattern 1100, the eleventh lower metal pattern 1110, the twelfth lower metal pattern 1120, and the thirteenth lower metal pattern 1130 may be spaced (e.g., spaced apart) from each other in a plan view.

The first lower metal pattern 1010 may be spaced apart from the second lower metal pattern 1020 in a direction opposite to the first direction DR1. The first lower metal pattern 1010 may extend in the second direction DR2. In an embodiment, the second power voltage ELVSS of FIG. 3 may be applied to the first lower metal pattern 1010. For example, the first lower metal pattern 1010 may be at least a portion of the second voltage line VL2 of FIG. 3.

The second lower metal pattern 1020 may be spaced (e.g., spaced apart) from the third lower metal pattern 1030, the fourth lower metal pattern 1040, and the fifth lower metal pattern 1050 in a direction opposite to the first direction DR1. The second lower metal pattern 1020 may extend in the second direction DR2. In one or more embodiments, the data voltage DT of FIG. 3 may be applied to the second lower metal pattern 1020. For example, a red data voltage may be applied to the second lower metal pattern 1020, but the present disclosure is not limited thereto. For example, the second lower metal pattern 1020 may be at least a portion of the data line DL of FIG. 3.

The third lower metal pattern 1030 may be spaced (e.g., spaced apart) from the fourth lower metal pattern 1040 in a direction opposite to the second direction DR2. In addition, the third lower metal pattern 1030 may be spaced (e.g., spaced apart) from the sixth lower metal pattern 1060 in a direction opposite to the first direction DR1.

The fourth lower metal pattern 1040 may be spaced (e.g., spaced apart) from the fifth lower metal pattern 1050 in a direction opposite to the second direction DR2. In addition, the fourth lower metal pattern 1040 may be spaced (e.g., spaced apart) from the sixth lower metal pattern 1060 in a direction opposite to the first direction DR1.

The fifth lower metal pattern 1050 may be spaced (e.g., spaced apart) from the sixth lower metal pattern 1060 in a direction opposite to the first direction DR1.

The sixth lower metal pattern 1060 may be spaced (e.g., spaced apart) from the seventh lower metal pattern 1070 in a direction opposite to the first direction DR1. The sixth lower metal pattern 1060 may extend in the second direction DR2. In one or more embodiments, the initialization voltage VINT of FIG. 3 may be applied to the sixth lower metal pattern 1060. For example, the sixth lower metal pattern 1060 may be at least a portion of the third voltage line VL3 of FIG. 3.

The seventh lower metal pattern 1070 may be spaced (e.g., spaced apart) from the eighth lower metal pattern 1080, the ninth lower metal pattern 1090, the tenth lower metal pattern 1100, and the eleventh lower metal pattern 1110 in a direction opposite to the first direction DR1. The seventh lower metal pattern 1070 may extend in the second direction DR2. In one or more embodiments, the first power supply voltage ELVDD of FIG. 3 may be applied to the seventh lower metal pattern 1070. For example, the seventh lower metal pattern 1070 may be at least a portion of the first voltage line VL1 of FIG. 3. For example, the seventh lower metal pattern 1070 may be referred to as a voltage line.

The eighth lower metal pattern 1080 may be spaced (e.g., spaced apart) from the twelfth lower metal pattern 1120 in a direction opposite to the first direction DR1. In addition, the eighth lower metal pattern 1080 may be spaced (e.g., spaced apart) from the ninth lower metal pattern 1090 in a direction opposite to the second direction DR2.

The ninth lower metal pattern 1090 may be spaced (e.g., spaced apart) from the twelfth lower metal pattern 1120 in a direction opposite to the first direction DR1. In addition, the ninth lower metal pattern 1090 may be spaced (e.g., spaced apart) from the tenth lower metal pattern 1100 in a direction opposite to the second direction DR2.

The tenth lower metal pattern 1100 may be spaced (e.g., spaced apart) from the twelfth lower metal pattern 1120 in a direction opposite to the first direction DR1. In addition, the tenth lower metal pattern 1100 may be spaced (e.g., spaced apart) from the eleventh lower metal pattern 1110 in a direction opposite to the second direction DR2.

The eleventh lower metal pattern 1110 may be spaced (e.g., spaced apart) from the twelfth lower metal pattern 1120 in a direction opposite to the first direction DR1.

The twelfth lower metal pattern 1120 may be spaced (e.g., spaced apart) from the thirteenth lower metal pattern 1130 in a direction opposite to the first direction DR1. The twelfth lower metal pattern 1120 may extend in the second direction DR2. In one or more embodiments, the data voltage DT of FIG. 3 may be applied to the twelfth lower metal pattern 1120. For example, a green data voltage may be applied to the twelfth lower metal pattern 1120, but the present disclosure is not limited thereto. For example, the twelfth lower metal pattern 1120 may be at least a portion of the data line DL of FIG. 3.

The thirteenth lower metal pattern 1130 may extend in the second direction DR2. In one or more embodiments, the data voltage DT of FIG. 3 may be applied to the thirteenth lower metal pattern 1130. For example, a blue data voltage may be applied to the thirteenth lower metal pattern 1130, but the present disclosure is not limited thereto. For example, the thirteenth lower metal pattern 1130 may be at least a portion of the data line DL of FIG. 3.

For example, the lower metal layer BML may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

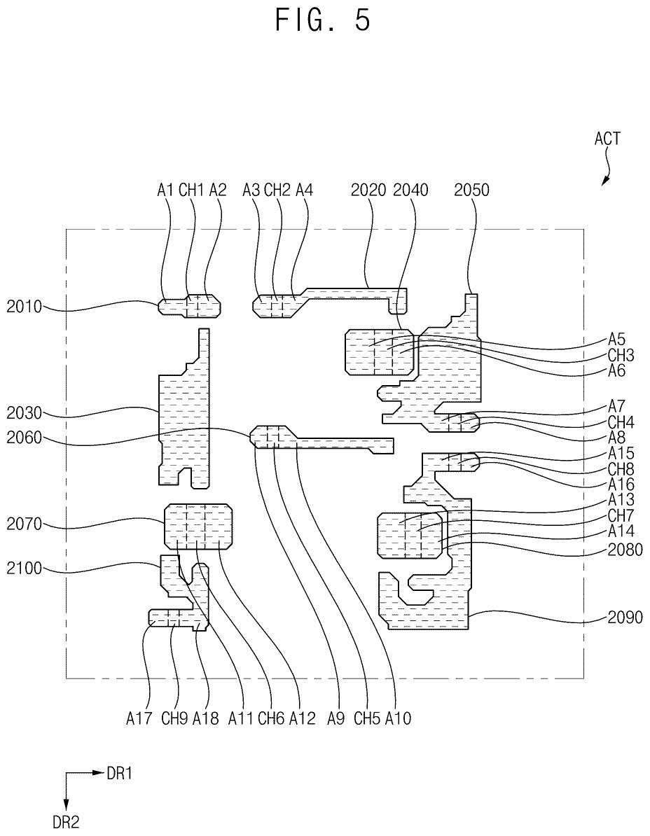

Referring to FIG. 5, an active layer ACT may be located on the lower metal layer (for example, the lower metal layer BML of FIG. 4). The active layer ACT may include a first active pattern 2010, a second active pattern 2020, a third active pattern 2030, a fourth active pattern 2040, a fifth active pattern 2050, a sixth active pattern 2060, a seventh active pattern 2070, an eighth active pattern 2080, a ninth active pattern 2090, and a tenth active pattern 2100.

The first active pattern 2010, the second active pattern 2020, the third active pattern 2030, the fourth active pattern 2040, the fifth active pattern 2050, the sixth active pattern 2060, the seventh active pattern 2070, the eighth active pattern 2080, the ninth active pattern 2090, and the tenth active pattern 2100 may be spaced (e.g., spaced apart) from each other in a plan view.

The first active pattern 2010 may include a first area A1, a first channel area CH1, and a second area A2. The first area A1 and the second area A2 may be spaced (e.g., spaced apart) from each other in a plan view. For example, the first area A1 and the second area A2 may be spaced (e.g., spaced apart) from each other with the first channel area CH1 interposed therebetween. For example, the first channel area CH1 may be located between the first area A1 and the second area A2. The first area A1 and the second area A2 may have higher conductivity than the first channel area CH1.

The second active pattern 2020 may include a third area A3, a second channel area CH2, and a fourth area A4. The third area A3 and the fourth area A4 may be spaced (e.g., spaced apart) from each other in a plan view. For example, the third area A3 and the fourth area A4 may be spaced (e.g., spaced apart) from each other with the second channel area CH2 interposed therebetween. For example, the second channel area CH2 may be located between the third area A3 and the fourth area A4. The third area A3 and the fourth area A4 may have higher conductivity than the second channel area CH2.

In one or more embodiments, the third active pattern 2030 may include a single area. For example, the third active pattern 2030 may include a single area having substantially constant conductivity across the third active pattern 2030, but the present disclosure is not limited thereto.

The fourth active pattern 2040 may include a fifth area A5, a third channel area CH3, and a sixth area A6. The fifth area A5 and the sixth area A6 may be spaced (e.g., spaced apart) from each other in a plan view. For example, the fifth area A5 and the sixth area A6 may be spaced (e.g., spaced apart) from each other with the third channel area CH3 interposed therebetween. For example, the third channel area CH3 may be located between the fifth area A5 and the sixth area A6. The fifth area A5 and the sixth area A6 may have higher conductivity than the third channel area CH3.

The fifth active pattern 2050 may include a seventh area A7, a fourth channel area CH4, and an eighth area A8. The seventh area A7 and the eighth area A8 may be spaced (e.g., spaced apart) from each other in a plan view. For example, the seventh area A7 and the eighth area A8 may be spaced (e.g., spaced apart) from each other with the fourth channel area CH4 interposed therebetween. For example, the fourth channel area CH4 may be located between the seventh area A7 and the eighth area A8. The seventh area A7 and the eighth area A8 may have higher conductivity than the fourth channel area CH4.

The sixth active pattern 2060 may include a ninth area A9, a fifth channel area CH5, and a tenth area A10. The ninth area A9 and the tenth area A10 may be spaced (e.g., spaced apart) from each other in a plan view. For example, the ninth area A9 and the tenth area A10 may be spaced (e.g., spaced apart) from each other with the fifth channel area CH5 interposed therebetween. For example, the fifth channel area CH5 may be located between the ninth area A9 and the tenth area A10. The ninth area A9 and the tenth area A10 may have higher conductivity than the fifth channel area CH5.

The seventh active pattern 2070 may include an eleventh area A11, a sixth channel area CH6, and a twelfth area A12. The eleventh area A11 and the twelfth area A12 may be spaced (e.g., spaced apart) from each other in a plan view. For example, the eleventh area A11 and the twelfth area A12 may be spaced (e.g., spaced apart) from each other with the sixth channel area CH6 interposed therebetween. For example, the sixth channel area CH6 may be located between the eleventh area A11 and the twelfth area A12. The eleventh area A11 and the twelfth area A12 may have higher conductivity than the sixth channel area CH6.

The eighth active pattern 2080 may include a thirteenth area A13, a seventh channel area CH7, and a fourteenth area A14. The thirteenth area A13 and the fourteenth area A14 may be spaced (e.g., spaced apart) from each other in a plan view. For example, the thirteenth area A13 and the fourteenth area A14 may be spaced (e.g., spaced apart) from each other with the seventh channel area CH7 interposed therebetween. For example, the seventh channel area CH7 may be located between the thirteenth area A13 and the fourteenth area A14. The thirteenth area A13 and the fourteenth area A14 may have higher conductivity than the seventh channel area CH7.

The ninth active pattern 2090 may include a fifteenth area A15, an eighth channel area CH8, and a sixteenth area A16. The fifteenth area A15 and the sixteenth area A16 may be spaced (e.g., spaced apart) from each other in a plan view. For example, the fifteenth area A15 and the sixteenth area A16 may be spaced (e.g., spaced apart) from each other with the eighth channel area CH8 interposed therebetween. For example, the eighth channel area CH8 may be located between the fifteenth area A15 and the sixteenth area A16. The fifteenth area A15 and the sixteenth area A16 may have higher conductivity than the eighth channel area CH8.

The tenth active pattern 2100 may include a seventeenth area A17, a ninth channel area CH9, and an eighteenth area A18. The seventeenth area A17 and the eighteenth areas A18 may be spaced (e.g., spaced apart) from each other in a plan view. For example, the seventeenth area A17 and the eighteenth area A18 may be spaced (e.g., spaced apart) from each other with the ninth channel area CH9 interposed therebetween. For example, the ninth channel area CH9 may be located between the seventeenth area A17 and the eighteenth area A18. The seventeenth area A17 and the eighteenth area A18 may have higher conductivity than the ninth channel area CH9.

For example, the active layer ACT may include an inorganic semiconductor (e.g., amorphous silicon, polysilicon, a metal oxide semiconductor), an organic semiconductor, and/or the like. These materials may be used alone or in combination with each other. The active layer ACT may include a source area, a drain area, and a channel area located between the source area and the drain area. The metal oxide semiconductor may include a binary compound (“ABₓ”), a ternary compound (“ABₓC_{y}”), a quaternary compound (“ABₓC_{y}D_{z}”), and/or the like including indium (“In”), zinc (“Zn”), gallium (“Ga”), tin (“Sn”), titanium (“Ti”), aluminum (“Al”), hafnium (“Hf”), zirconium (“Zr”), magnesium (“Mg”), and/or the like. These materials may be used alone or in combination with each other. For example, the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), and/or indium gallium zinc oxide (“IGZO”). These materials may be used alone or in combination with each other.

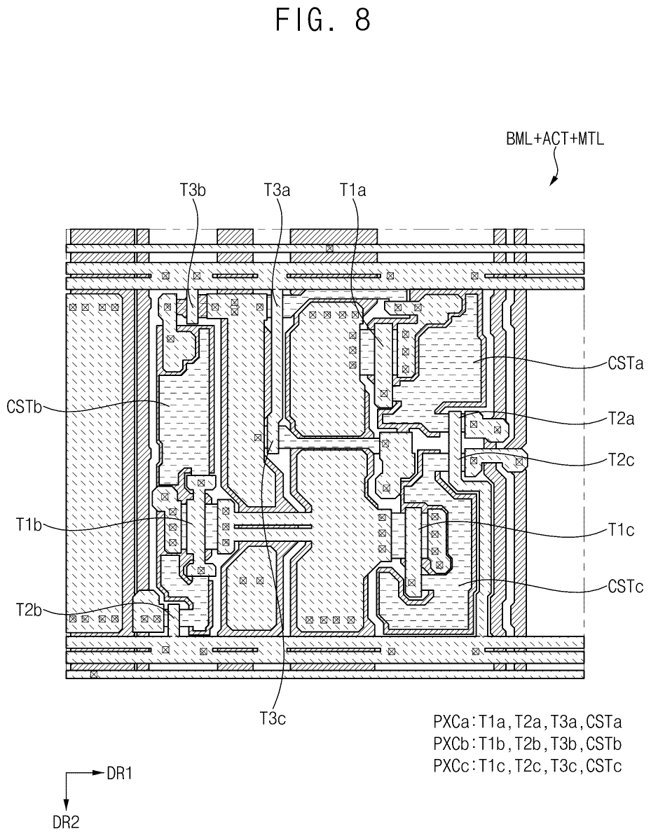

Referring to FIGS. 4, 5, and 6, a capacitor CSTa may include a portion of the ninth lower metal pattern 1090 and a portion of the fifth active pattern 2050. For example, the capacitor CSTa may include a portion of the seventh area A7 and a portion of the ninth lower metal pattern 1090. The portion of the seventh area A7 and the portion of the ninth lower metal pattern 1090 may overlap each other in a plan view. The capacitor CSTa may be a capacitor included in a first pixel driving circuit portion PXCa of FIG. 8.

A capacitor CSTb may include a portion of the fourth lower metal pattern 1040 and a portion of the third active pattern 2030. The portion of the fourth lower metal pattern 1040 and the portion of the third active pattern 2030 may overlap each other in a plan view. The capacitor CSTb may be a capacitor included in a second pixel driving circuit portion PXCb of FIG. 8.

A capacitor CSTc may include a portion of the tenth lower metal pattern 1100 and a portion of the ninth active pattern 2090. For example, the capacitor CSTc may include a portion of the fifteenth area A15 and a portion of the tenth lower metal pattern 1100. The portion of the fifteenth area A15 and the portion of the tenth lower metal pattern 1100 may overlap each other in a plan view. The capacitor CSTc may be a capacitor included in a third pixel driving circuit portion PXCc of FIG. 8.

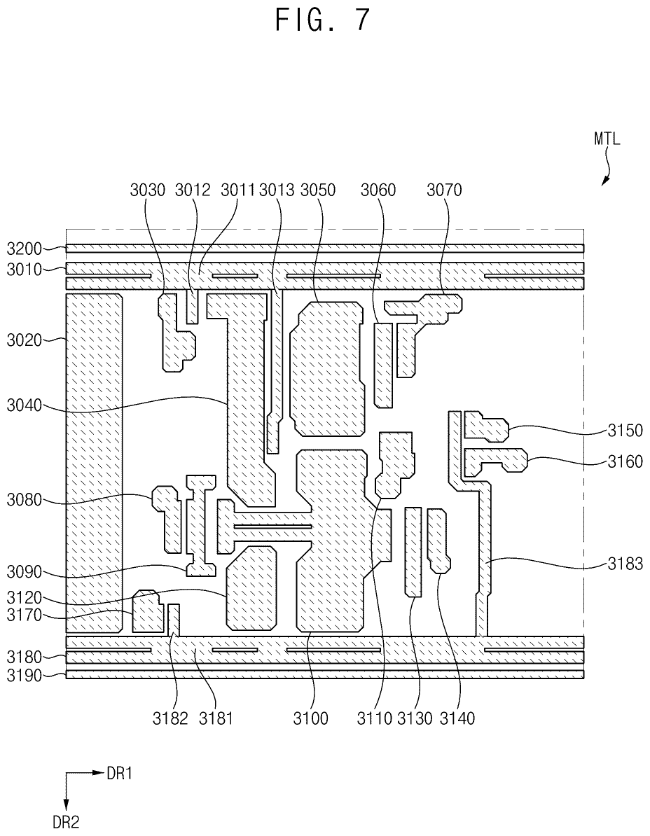

Referring to FIG. 7, the metal layer MTL may be located on the active layer (for example, the active layer ACT of FIG. 5). The metal layer MTL may include a first metal pattern 3010, a second metal pattern 3020, a third metal pattern 3030, a fourth metal pattern 3040, a fifth metal pattern 3050, a sixth metal pattern 3060, a seventh metal pattern 3070, an eighth metal pattern 3080, a ninth metal pattern 3090, a tenth metal pattern 3100, a eleventh metal pattern 3110, a twelfth metal pattern 3120, a thirteenth metal pattern 3130, a fourteenth metal 3140, a fifteenth metal pattern 3150, a sixteenth metal pattern 3160, a seventeenth metal pattern 3170, an eighteenth metal pattern 3180, a nineteenth metal pattern 3190, and a twentieth metal pattern 3200.

The first metal pattern 3010, the second metal pattern 3020, the third metal pattern 3030, the fourth metal pattern 3040, the fifth metal pattern 3050, the sixth metal pattern 3060, the seventh metal pattern 3070, the eighth metal pattern 3080, the ninth metal pattern 3090, the tenth metal pattern 3100, the eleventh metal pattern 3110, the twelfth metal pattern 3120, the thirteenth metal pattern 3130, the fourteenth metal 3140, the fifteenth metal pattern 3150, the sixteenth metal pattern 3160, the seventeenth metal pattern 3170, the eighteenth metal pattern 3180, the nineteenth metal pattern 3190, and the twentieth metal pattern 3200 may be spaced (e.g., spaced apart) from each other in a plan view.

In one or more embodiments, the first metal pattern 3010 may include a first portion 3011, a second portion 3012, and a third portion 3013. The first portion 3011 may extend in the first direction DR1. Each of the second portion 3012 and the third portion 3013 may be a portion extending from the first portion 3011. For example, each of the second portion 3012 and the third portion 3013 may be a portion extending in the second direction DR2 from the first portion 3011. In one or more embodiments, the sensing signal SS of FIG. 3 may be applied to the first metal pattern 3010. For example, the first metal pattern 3010 may be at least a portion of the sensing signal line SSL of FIG. 3.

The second metal pattern 3020 may be located between the first portion 3011 and a first portion 3181 of the eighteenth metal pattern 3180 to be described later. In addition, the second metal pattern 3020 may be spaced (e.g., spaced apart) from the third metal pattern 3030, the eighth metal pattern 3080, and the seventeenth metal pattern 3170 in a direction opposite to the first direction DR1. The second metal pattern 3020 may extend in the second direction DR2.

The third metal pattern 3030 may be spaced (e.g., spaced apart) from the first portion 3011 in the second direction DR2. In addition, the third metal pattern 3030 may be spaced (e.g., spaced apart) from the fourth metal pattern 3040 in a direction opposite to the first direction DR1. In addition, the third metal pattern 3030 may be spaced (e.g., spaced apart) from the eighth metal pattern 3080 in a direction opposite to the second direction DR2.

The fourth metal pattern 3040 may be located between the second portion 3012 and the third portion 3013 in a plan view. In addition, the fourth metal pattern 3040 may be spaced (e.g., spaced apart) from the first portion 3011 in the second direction DR2.

The fifth metal pattern 3050 may be spaced (e.g., spaced apart) from the first portion 3011 in the second direction DR2. In addition, the fifth metal pattern 3050 may be spaced (e.g., spaced apart) from the third portion 3013 in the first direction DR1. In addition, the fifth metal pattern 3050 may be spaced (e.g., spaced apart) from the sixth metal pattern 3060 in a direction opposite to the first direction DR1.

The sixth metal pattern 3060 may be spaced (e.g., spaced apart) from the first portion 3011 in the second direction DR2. In addition, the sixth metal pattern 3060 may be spaced (e.g., spaced apart) from the eleventh metal pattern 3110 in a direction opposite to the second direction DR2. In addition, the sixth metal pattern 3060 may be spaced (e.g., spaced apart) from the seventh metal pattern 3070 in a direction opposite to the first direction DR1.

The seventh metal pattern 3070 may be spaced (e.g., spaced apart) from the first portion 3011 in the second direction DR2. In addition, the seventh metal pattern 3070 may be spaced (e.g., spaced apart) from the eleventh metal pattern 3110 in a direction opposite to the second direction DR2.

The eighth metal pattern 3080 may be spaced (e.g., spaced apart) from the ninth metal pattern 3090 in a direction opposite to the first direction DR1. For example, the eighth metal pattern 3080 may be located between the second metal pattern 3020 and the ninth metal pattern 3090 in a plan view.

The ninth metal pattern 3090 may be spaced (e.g., spaced apart) from the tenth metal pattern 3100 in a direction opposite to the first direction DR1. For example, the ninth metal pattern 3090 may be located between the eighth metal pattern 3080 and the tenth metal pattern 3100 in a plan view.

The tenth metal pattern 3100 may be spaced (e.g., spaced apart) from the thirteenth metal pattern 3130 in a direction opposite to the first direction DR1. For example, the tenth metal pattern 3100 may be located between the ninth metal pattern 3090 and the thirteenth metal pattern 3130 in a plan view.

The eleventh metal pattern 3110 may be spaced (e.g., spaced apart) from the fifteenth metal pattern 3150 and the sixteenth metal pattern 3160 in a direction opposite to the first direction DR1. In addition, the eleventh metal pattern 3110 may be spaced (e.g., spaced apart) from the thirteenth metal pattern 3130 in a direction opposite to the second direction DR2.

The twelfth metal pattern 3120 may be spaced (e.g., spaced apart) from the first portion 3181 of the eighteenth metal pattern 3180 in a direction opposite to the second direction DR2. In addition, the twelfth metal pattern 3120 may be spaced (e.g., spaced apart) from a second portion 3182 of the eighteenth metal pattern 3180 to be described later in the first direction DR1.

The thirteenth metal pattern 3130 may be spaced (e.g., spaced apart) from the fourteenth metal pattern 3140 in a direction opposite to the first direction DR1. In addition, the thirteenth metal pattern 3130 may be spaced (e.g., spaced apart) from the first portion 3181 of the eighteenth metal pattern 3180 in a direction opposite to the second direction DR2.

The fourteenth metal pattern 3140 may be spaced (e.g., spaced apart) from a third portion 3183 of the eighteenth metal pattern 3180 to be described later in a direction opposite to the first direction DR1. In addition, the fourteenth metal pattern 3140 may be spaced (e.g., spaced apart) from the first portion 3181 in a direction opposite to the second direction DR2.

The fifteenth metal pattern 3150 may be spaced (e.g., spaced apart) from the third portion 3183 of the eighteenth metal pattern 3180 in the first direction DR1. In addition, the fifteenth metal pattern 3150 may be spaced (e.g., spaced apart) from the sixteenth metal pattern 3160 in a direction opposite to the second direction DR2.

The sixteenth metal pattern 3160 may be located adjacent to the third portion 3183 of the eighteenth metal pattern 3180.

The seventeenth metal pattern 3170 may be spaced (e.g., spaced apart) from the second portion 3182 of the eighteenth metal pattern 3180 in a direction opposite to the first direction DR1. For example, the seventeenth metal pattern 3170 may be located between the second metal pattern 3020 and the second portion 3182 of the eighteenth metal pattern 3180 in a plan view.

In one or more embodiments, the eighteenth metal pattern 3180 may include a first portion 3181, a second portion 3182, and a third portion 3183. The first portion 3181 may extend in the first direction DR1. Each of the second portion 3182 and the third portion 3183 may be a portion extending from the first portion 3181. For example, each of the second portion 3182 and the third portion 3183 may be portions extending from the first portion 3181 in a direction opposite to the second direction DR2. In one or more embodiments, the scan signal SC of FIG. 3 may be applied to the eighteenth metal pattern 3180. For example, the eighteenth metal pattern 3180 may be at least a portion of the scan signal line SCL of FIG. 3.

The nineteenth metal pattern 3190 may be spaced (e.g., spaced apart) from the eighteenth metal pattern 3180 in the second direction DR2. The nineteenth metal pattern 3190 may extend in the first direction DR1.

The twentieth metal pattern 3200 may be spaced (e.g., spaced apart) from the first metal pattern 3010 in a direction opposite to the second direction DR2. For example, the twentieth metal pattern 3200 may be spaced (e.g., spaced apart) from the first portion 3011 of the first metal pattern 3010 in a direction opposite to the second direction DR2. The twentieth metal pattern 3200 may extend in the first direction DR1.

For example, the metal layer MTL may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

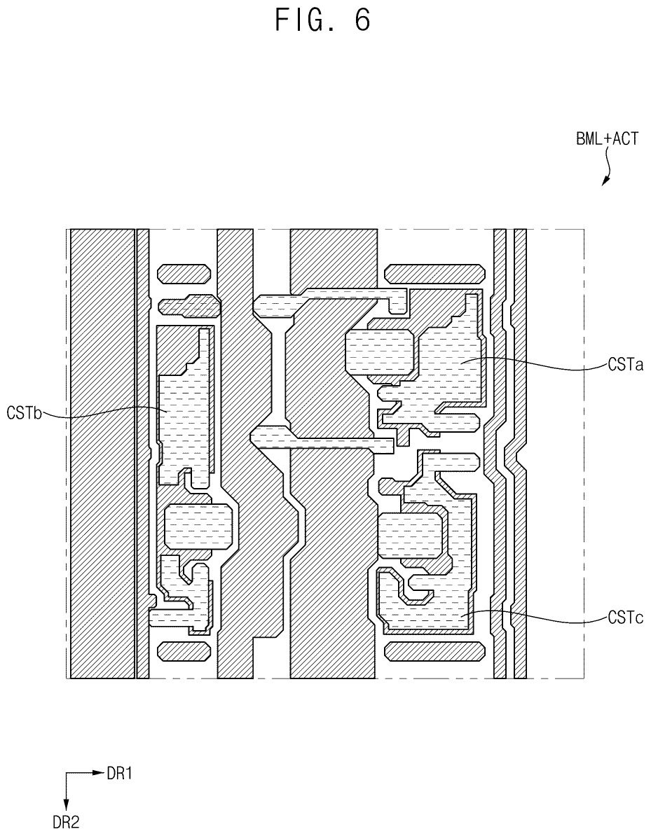

Referring to FIGS. 6, 7, and 8, a portion of the metal layer MTL may be connected to a portion of the lower metal layer BML through a contact hole. In addition, a portion of the metal layer MTL may be connected to a portion of the active layer ACT through a contact hole. As illustrated in FIG. 8, the contact hole is indicated by an “X” in a square box.

In one or more embodiments, the display device (e.g., the display device DD of FIG. 2) may include a first pixel driving circuit portion PXCa, a second pixel driving circuit portion PXCb, and a third pixel driving circuit portion PXCc. For example, the first pixel driving circuit portion PXCa is included in the first pixel PX1 of FIG. 2, the second pixel driving circuit portion PXCb is included in the second pixel PX2 of FIG. 2, and the third pixel driving circuit portion PXCc may be included in the third pixel PX3 of FIG. 2, but the present disclosure is not limited thereto. In addition, each of the first pixel driving circuit portion PXCa, the second pixel driving circuit portion PXCb, and the third pixel driving circuit portion PXCc may have substantially same structure as the pixel driving circuit portion PXC of FIG. 3, but the present disclosure is not limited thereto.

The first pixel driving circuit portion PXCa may include a first transistor T1a, a second transistor T2a, a third transistor T3a, and a capacitor CSTa. The first transistor T1a may correspond to the first transistor T1 of FIG. 3, the second transistor T2a may correspond to the second transistor T2 of FIG. 3, the third transistor T3a may correspond to the third transistor T3 of FIG. 3, and the capacitor CSTa may correspond to the capacitor CST of FIG. 3.

The second pixel driving circuit portion PXCb may include a first transistor T1b, a second transistor T2b, a third transistor T3b, and a capacitor CSTb. The first transistor T1b may correspond to the first transistor T1 of FIG. 3, the second transistor T2b may correspond to the second transistor T2 of FIG. 3, the third transistor T3b may correspond to the third transistor T3 of FIG. 3, and the capacitor CSTb may correspond to the capacitor CST of FIG. 3.

The third pixel driving circuit portion PXCc may include a first transistor T1c, a second transistor T2c, a third transistor T3c, and a capacitor CSTc. The first transistor T1c may correspond to the first transistor T1 of FIG. 3, the second transistor T2c may correspond to the second transistor T2 of FIG. 3, the third transistor T3c may correspond to the third transistor T3 of FIG. 3, and the capacitor CSTc may correspond to the capacitor CST of FIG. 3.

The first transistor T1a may include a portion of the fourth active pattern 2040 (i.e., a portion of the fifth area A5, a portion of the sixth area A6, and the third channel area CH3) and a portion of the sixth metal pattern 3060 overlapping the third channel area CH3 in a plan view. For example, the portion of the sixth metal pattern 3060 overlapping the third channel area CH3 in a plan view may be referred to as a gate electrode of the first transistor T1a.

The second transistor T2a may include a portion of the fifth active pattern 2050 (i.e., a portion of the seventh area A7, a portion of the eighth area A8, and the fourth channel area CH4) and a portion of the third portion 3183 of the eighteenth metal pattern 3180 overlapping the fourth channel area CH4 in a plan view. For example, the portion of the third portion 3183 of the eighteenth metal pattern 3180 overlapping the fourth channel area CH4 in a plan view may be referred to as a gate electrode of the second transistor T2a.

The third transistor T3a may include a portion of the second active pattern 2020 (i.e., a portion of the third area A3, a portion of the fourth area A4, and the second channel area CH2) and a portion of the third portion 3013 of the first metal pattern 3010 overlapping the second channel area CH2 in a plan view. For example, the portion of the third portion 3013 of the first metal pattern 3010 overlapping the second channel area CH2 in a plan view may be referred to as a gate electrode of the third transistor T3a.

The first transistor T1b may include a portion of the seventh active pattern 2070 (i.e., a portion of the eleventh area A11, a portion of the twelfth area A12, and the sixth channel area CH6) and a portion of the ninth metal pattern 3090 overlapping the sixth channel area CH6 in a plan view. For example, the portion of the ninth metal pattern 3090 overlapping the sixth channel area CH6 in a plan view may be referred to as a gate electrode of the first transistor T1b.

The second transistor T2b may include a portion of the tenth active pattern 2100 (i.e., a portion of the seventeenth area A17, a portion of the eighteenth area A18, and the ninth channel area CH9) and a portion of the second portion 3182 of the eighteenth metal pattern 3180 overlapping the ninth channel area CH9 in a plan view. For example, a portion of the second portion 3182 of the eighteenth metal pattern 3180 overlapping the ninth channel area CH9 in a plan view may be referred to as a gate electrode of the second transistor T2b.

The third transistor T3b may include a portion of the first active pattern 2010 (i.e., a portion of the first area A1, a portion of the second area A2, and the first channel area CH1) and a portion of the second portion 3012 of the first metal pattern 3010 overlapping the first channel area CH1 in a plan view. For example, the portion of the second portion 3012 of the first metal pattern 3010 overlapping the first channel area CH1 in a plan view may be referred to as a gate electrode of the third transistor T3b.

The first transistor T1c may include a portion of the eighth active pattern 2080 (i.e., a portion of the thirteenth area A13, a portion of the fourteenth area A14, and the seventh channel area CH7) and a portion of the thirteenth metal pattern 3130 overlapping the seventh channel area CH7 in a plan view. For example, the portion of the thirteenth metal pattern 3130 overlapping the seventh channel area CH7 in a plan view may be referred to as a gate electrode of the first transistor T1c.

The second transistor T2c may include a portion of the ninth active pattern 2090 (i.e., a portion of the fifteenth area A15, a portion of the sixteenth area A16, and the eighth channel area CH8) and a portion of the third portion 3183 of the eighteenth metal pattern 3180 overlapping the eighth channel area CH8 in a plan view. For example, the portion of the third portion 3183 of the eighteenth metal pattern 3180 overlapping the eighth channel area CH8 in a plan view may be referred to as a gate electrode of the second transistor T2c.

The third transistor T3c may include a portion of the sixth active pattern 2060 (i.e., a portion of the ninth area A9, a portion of the tenth area A10, and the fifth channel area CH5) and a portion of the third portion 3013 of the first metal pattern 3010 overlapping the fifth channel area CH5 in a plan view. For example, the portion of the third portion 3013 of the first metal pattern 3010 overlapping the fifth channel area CH5 in a plan view may be referred to as a gate electrode of the third transistor T3c.

Referring further to FIG. 4, in one or more embodiments, the first transistor T1a may be located at one side of the seventh lower metal pattern 1070. For example, the first transistor T1a may be spaced (e.g., spaced apart) from the seventh lower metal pattern 1070 in the first direction DR1. In addition, the first transistor T1b may be located at other side of the seventh lower metal pattern 1070. For example, the first transistor T1b may be spaced (e.g., spaced apart) from the seventh lower metal pattern 1070 in a direction opposite to the first direction DR1. In addition, the first transistor T1c may be located at one side of the seventh lower metal pattern 1070. For example, the first transistor T1c may be spaced (e.g., spaced apart) from the seventh lower metal pattern 1070 in the first direction DR1. As described above, the first power voltage ELVDD of FIG. 3 may be applied to the seventh lower metal pattern 1070, and the seventh lower metal pattern 1070 may be referred to as the voltage line. Each of the first transistor T1a and the first transistor T1c may be located at one side of the voltage line, and the first transistor T1b may be located at other side of the voltage line.

In one or more embodiments, the second transistor T2a may be located at one side of the seventh lower metal pattern 1070. For example, the second transistor T2a may be spaced (e.g., spaced apart) from the seventh lower metal pattern 1070 in the first direction DR1. In addition, the second transistor T2b may be located at other side of the seventh lower metal pattern 1070. For example, the second transistor T2b may be spaced (e.g., spaced apart) from the seventh lower metal pattern 1070 in a direction opposite to the first direction DR1. In addition, the second transistor T2c may be located at one side of the seventh lower metal pattern 1070. For example, the second transistor T2c may be spaced (e.g., spaced apart) from the seventh lower metal pattern 1070 in the first direction DR1. Each of the second transistor T2a and the second transistor T2c may be located at one side of the voltage line, and the second transistor T2b may be located at other side of the voltage line.

In one or more embodiments, the third transistor T3a may be located at other side of the seventh lower metal pattern 1070. For example, the third transistor T3a may be spaced (e.g., spaced apart) from the seventh lower metal pattern 1070 in a direction opposite to the first direction DR1. In addition, the third transistor T3b may be located at other side of the seventh lower metal pattern 1070. For example, the third transistor T3b may be spaced (e.g., spaced apart) from the seventh lower metal pattern 1070 in a direction opposite to the first direction DR1. In addition, the third transistor T3c may be located at other side of the seventh lower metal pattern 1070. For example, the third transistor T3c may be spaced (e.g., spaced apart) from the seventh lower metal pattern 1070 in a direction opposite to the first direction DR1. Each of the third transistor T3a, the third transistor T3b, and the third transistor T3c may be located at other side of the voltage line.

In one or more embodiments, the capacitor CSTa may be located at one side of the seventh lower metal pattern 1070. For example, the capacitor CSTa may be spaced (e.g., spaced apart) from the seventh lower metal pattern 1070 in the first direction DR1. In addition, the capacitor CSTb may be located at other side of the seventh lower metal pattern 1070. For example, the capacitor CSTb may be spaced (e.g., spaced apart) from the seventh lower metal pattern 1070 in a direction opposite to the first direction DR1. In addition, the capacitor CSTc may be located at one side of the seventh lower metal pattern 1070. For example, the capacitor CSTc may be spaced (e.g., spaced apart) from the seventh lower metal pattern 1070 in the first direction DR1. Each of the capacitor CSTa and the capacitor CSTc may be located at one side of the voltage line, and the capacitor CSTb may be located at other side of the voltage line.

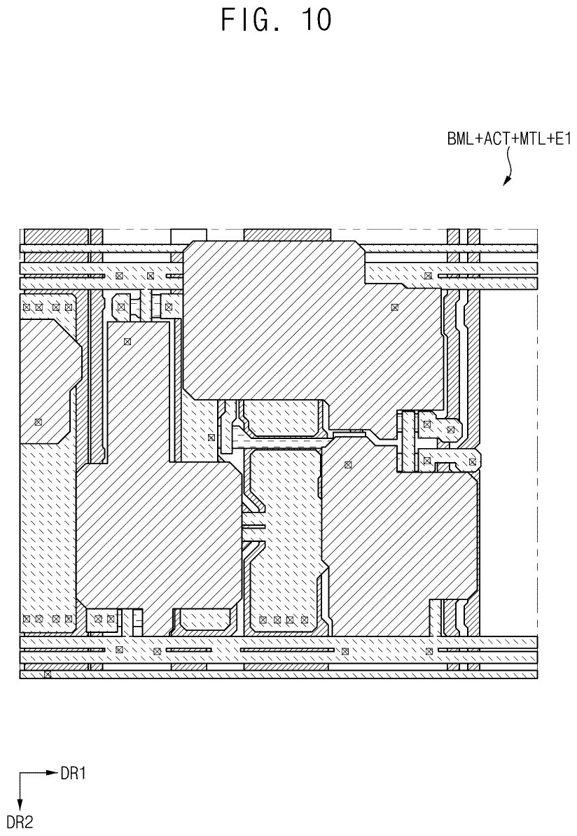

Referring to FIGS. 8, 9, and 10, a lower electrode layer E1 may be located on the metal layer MTL. The lower electrode layer E1 may include a first lower electrode pattern E1a, a second lower electrode pattern E1b, a third lower electrode pattern E1c, and a fourth lower electrode pattern E1d. The first lower electrode pattern E1a, the second lower electrode pattern E1b, the third lower electrode pattern E1c, and the fourth lower electrode pattern E1d may be spaced (e.g., spaced apart) from each other in a plan view. For example, the lower electrode layer E1 may have a stack structure including ITO/Ag/ITO, but the present disclosure is not limited thereto. A portion of the lower electrode layer E1 may be connected to a portion of the metal layer MTL through a contact hole. As illustrated in FIG. 10, the contact hole is indicated by an “X” in a square box.

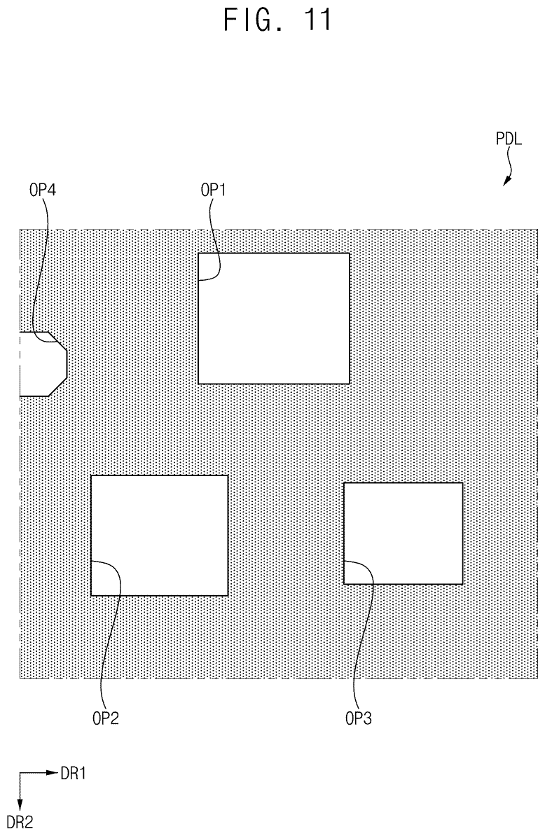

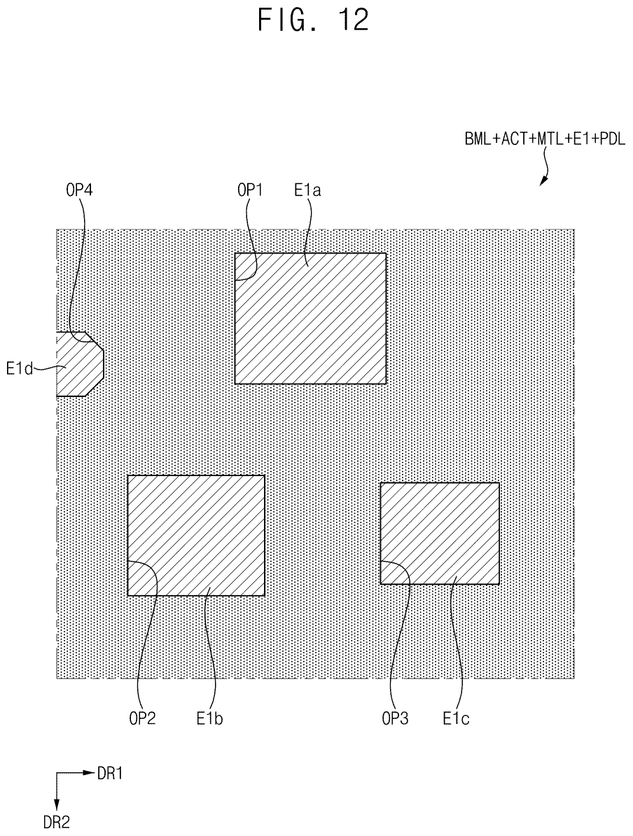

Referring to FIGS. 11 and 12, a pixel defining layer PDL may be located on the lower electrode layer E1. For example, the pixel defining layer PDL may cover the lower electrode layer E1. In one or more embodiments, the pixel defining layer PDL may define a first opening OP1, a second opening OP2, a third opening OP3, and a fourth opening OP4. The first opening OP1 may expose at least a portion of an upper surface of the first lower electrode pattern Ela. In addition, the second opening OP2 may expose at least a portion of an upper surface of the second lower electrode pattern E1b. In addition, the third opening OP3 may expose at least a portion of an upper surface of the third lower electrode pattern E1c. In addition, the fourth opening OP4 may expose at least a portion of an upper surface of the fourth lower electrode pattern E1d. The first opening OP1, the second opening OP2, the third opening OP3 and the fourth opening OP4 may be spaced (e.g., spaced apart) from each other in a plan view.

For example, the pixel defining layer PDL may include an inorganic material and/or an organic material. In one or more embodiments, the pixel defining layer PDL may include an organic material such as an epoxy resin, a siloxane resin, and/or the like. These materials may be used alone or in combination with each other. In one or more embodiments, the pixel defining layer PDL may further include a light blocking material including a black pigment and/or a black dye.

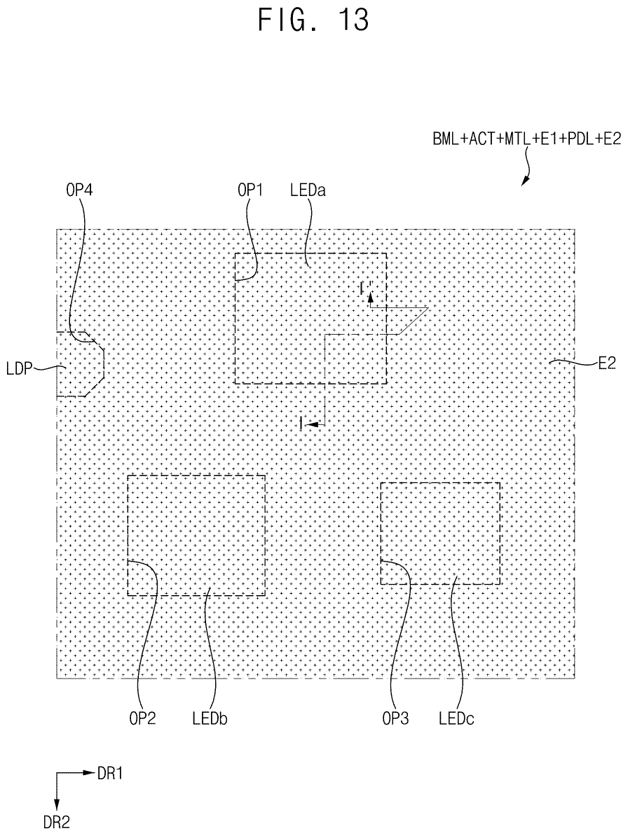

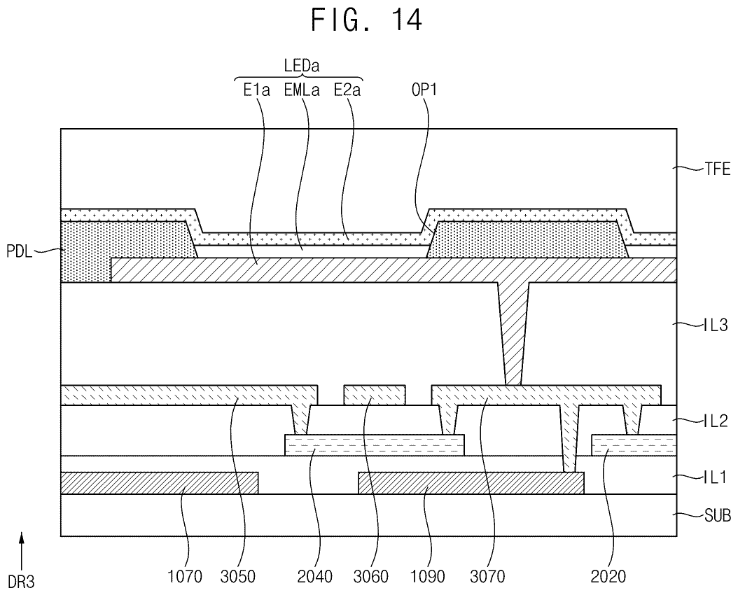

Referring to FIGS. 12 and 13, an upper electrode layer E2 may be located on the pixel defining layer PDL and the lower electrode layer E1. In one or more embodiments, the upper electrode layer E2 may be located over entire display area (e.g., the display area DA of FIG. 2). For example, a portion of the upper electrode layer E2 located in the first opening OP1 may be referred to as a first upper electrode pattern (e.g., a first upper electrode pattern E2a of FIG. 14), and a portion of the upper electrode layer E2 located in the second opening OP2 may be referred to as a second upper electrode pattern, and a portion of the upper electrode layer E2 located in the third opening OP3 may be referred to as a third upper electrode pattern, and a portion of the upper electrode layer E2 located in the fourth opening OP4 may be referred to as a fourth upper electrode pattern.

For example, the upper electrode layer E2 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

A first light emitting element LEDa may be located in the first opening OP1. The first light emitting element LEDa may be included in the first pixel PX1 of FIG. 2. For example, the first pixel PX1 of FIG. 2 may include the first light emitting element LEDa and the first pixel driving circuit portion (e.g., the first pixel driving circuit portion PXCa of FIG. 8) electrically connected to the first light emitting element LEDa.

The first light emitting element LEDa may include a first lower metal pattern E1a, a first intermediate layer (e.g., a first intermediate layer EMLa of FIG. 14), and the first upper metal pattern. The first intermediate layer may be located between the first lower metal pattern E1a and the first upper metal pattern. The first lower metal pattern Ela may be an anode of the first light emitting element LEDa, and the first upper metal pattern may be a cathode of the first light emitting element LEDa.

The second light emitting element LEDb may be located in the second opening OP2. The second light emitting element LEDb may be included in the second pixel PX2 of FIG. 2. For example, the second pixel PX2 of FIG. 2 may include the second light emitting element LEDb and the second pixel driving circuit portion (for example, the second pixel driving circuit portion PXCb of FIG. 8) electrically connected to the second light emitting element LEDb.

The second light emitting element LEDb may include the second lower metal pattern E1b, a second intermediate layer, and the second upper metal pattern. The second intermediate layer may be located between the second lower metal pattern E1b and the second upper metal pattern. The second lower metal pattern E1b may be an anode of the second light emitting element LEDb, and the second upper metal pattern may be a cathode of the second light emitting element LEDb.

The third light emitting element LEDc may be located in the third opening OP3. The third light emitting element LEDc may be included in the third pixel PX3 of FIG. 2. For example, the third pixel PX3 of FIG. 2 may include the third light emitting element LEDc and the third pixel driving circuit portion (for example, the third pixel driving circuit portion PXCc of FIG. 8) electrically connected to the third light emitting element LEDc.

The third light emitting element LEDc may include the third lower metal pattern E1c, a third intermediate layer, and the third upper metal pattern. The third intermediate layer may be located between the third lower metal pattern E1c and the third upper metal pattern. The third lower metal pattern E1c may be an anode of the third light emitting element LEDc, and the third upper metal pattern may be a cathode of the third light emitting element LEDc.

Each of the first intermediate layer, the second intermediate layer, and the third intermediate layer may include a first functional layer, a light emitting layer located on the first functional layer, and a second functional layer located on the light emitting layer. For example, the first functional layer may include a hole injection layer, a hole transport layer, and/or the like, and the second functional layer may include an electron transport layer, an electron injection layer, and/or the like. The first intermediate layer may be illustrated in FIG. 14.

In one or more embodiments, the first light emitting element LEDa, the second light emitting element LEDb, and the third light emitting element LEDc may emit light having different wavelengths to each other. For example, the first light emitting element LEDa may emit green light, the second light emitting element LEDb may emit red light, and the third light emitting element LEDc may emit blue light, but the present disclosure is not limited thereto. In one or more embodiments, the first light emitting element LEDa, the second light emitting element LEDb, and the third light emitting element LEDc may be spaced (e.g., spaced apart) from each other in a plan view.

A contact portion LDP may be located in the fourth opening OP4. The contact portion LDP may be a portion where the fourth lower electrode pattern E1d and the fourth upper electrode pattern contact with each other through the fourth opening OP4. The fourth lower electrode pattern E1d may be connected to the first lower metal pattern 1010 of FIG. 4 through a contact hole. The second power voltage ELVSS of FIG. 3 may be applied to the first lower metal pattern 1010 of FIG. 4. For example, in the fourth opening OP4, the fourth upper electrode pattern may be connected to the first lower metal pattern 1010 of FIG. 4 through the fourth lower electrode pattern E1d. Accordingly, an IR-drop phenomenon of the upper electrode layer E2 may be prevented.

Referring further to FIGS. 8 and 13, each of the first light emitting element LEDa, the second light emitting element LEDb, and the third light emitting element LEDc may emit light in all directions. For example, light emitted from the first light emitting element LEDa may reach the second pixel driving circuit portion PXCb and the third pixel driving circuit portion PXCc. In addition, light emitted from the second light emitting element LEDb may reach the first pixel driving circuit portion PXCa and the third pixel driving circuit portion PXCc. In addition, light emitted from the third light emitting element LEDc may reach the first pixel driving circuit portion PXCa and the second pixel driving circuit portion PXCb.

In one or more embodiments, the first transistor T1a may at least partially overlap the first light emitting element LEDa in a plan view. In addition, the first transistor T1b may at least partially overlap the second light emitting element LEDb in a plan view. In addition, the first transistor T1c may at least partially overlap the third light emitting element LEDc in a plan view. Accordingly, a sufficient separation distance in a plan view between the first transistor T1a and the second light emitting element LEDb may be secured. In addition, a sufficient separation distance in a plan view between the first transistor T1a and the third light emitting element LEDc may be secured. Accordingly, light emitted from each of the second light emitting element LEDb and the third light emitting element LEDc may be prevented from reaching the first transistor T1a. Alternatively, only a small portion of the light emitted from each of the second light emitting element LEDb and the third light emitting element LEDc may reach the first transistor T1a. Accordingly, deterioration of the first transistor T1a may be prevented or reduced.

In addition, a sufficient separation distance in a plan view between the first transistor T1b and the first light emitting element LEDa may be secured. In addition, a sufficient separation distance in a plan view between the first transistor T1b and the third light emitting element LEDc may be secured. Accordingly, light emitted from each of the first light emitting element LEDa and the third light emitting element LEDc may be prevented from reaching the first transistor T1b. Alternatively, only a small portion of the light emitted from each of the first light emitting element LEDa and the third light emitting element LEDc may reach the first transistor T1b. Accordingly, deterioration of the first transistor T1b may be prevented or reduced.

In addition, a sufficient separation distance in a plan view between the first transistor T1c and the first light emitting element LEDa may be secured. In addition, a sufficient separation distance in a plan view between the first transistor T1c and the second light emitting element LEDb may be secured. Accordingly, light emitted from each of the first light emitting element LEDa and the second light emitting element LEDb may be prevented from reaching the first transistor T1c. Alternatively, only a small portion of the light emitted from each of the first light emitting element LEDa and the second light emitting element LEDb may reach the first transistor T1c. Accordingly, deterioration of the first transistor T1c may be prevented or reduced.

For example, the first transistor Ta may not be affected by light emitted from light emitting elements adjacent to the first transistor T1a. In addition, the first transistor T1b may not be affected by light emitted from light emitting elements adjacent to the first transistor T1b. In addition, the first transistor T1c may not be affected by light emitted from light emitting elements adjacent to the first transistor T1c.

In addition, as described above, each of the first transistor T1a and the first transistor T1c may be located at one side of the voltage line, and the first transistor T1b may be located at other side of the voltage line. Accordingly, a sufficient separation distance in a plan view between the first transistor T1a and the second light emitting element LEDb may be secured. In addition, a sufficient separation distance in a plan view between the first transistor T1b and the first light emitting element LEDa may be secured. In addition, a sufficient separation distance in a plan view between the first transistor T1b and the third light emitting element LEDc may be secured. In addition, a sufficient separation distance in a plan view between the first transistor T1c and the second light emitting element LEDb may be secured. Accordingly, deterioration of each of the first transistor T1a, the first transistor T1b, and the first transistor T1c may be prevented or reduced.

In addition, as described above, each of the second transistor T2a and the second transistor T2c may be located at one side of the voltage line, and the second transistor T2b may be located at other side of the voltage line. Accordingly, a separation distance in a plan view between the second transistor T2a and the second light emitting element LEDb may be secured. Accordingly, light emitted from the second light emitting element LEDb may be prevented from reaching the second transistor T2a. Accordingly, deterioration of the second transistor T2a may be prevented or reduced. In addition, a separation distance in a plan view between the second transistor T2b and the first light emitting element LEDa may be secured. In addition, a separation distance in a plan view between the second transistor T2b and the third light emitting element LEDc may be secured. Accordingly, light emitted from the first light emitting element LEDa and the third light emitting element LEDc may be prevented from reaching the second transistor T2b. Accordingly, deterioration of the second transistor T2b may be prevented. In addition, a separation distance in a plan view between the second transistor T2c and the second light emitting element LEDb may be secured. Accordingly, light emitted from the second light emitting element LEDb may be prevented from reaching the second transistor T2c. Accordingly, deterioration of the second transistor T2c may be prevented or reduced.

FIG. 14 is a cross-sectional view of the display device of FIG. 13 taken along the line I-I′.

Referring to FIG. 14, the substrate SUB may be a base of the display device (e.g., the display device DD of FIG. 1). The substrate SUB may be formed of a transparent resin substrate. Example of the transparent resin substrate may include a polyimide substrate. In this case, the polyimide substrate may include a first organic layer, a first barrier layer, a second organic layer, and/or the like. Optionally, the substrate SUB may include a quartz substrate (e.g. a synthetic quartz substrate, a fluorine-doped quartz substrate), a calcium fluoride substrate, a sodalime glass substrate, a non-alkali glass substrate, and/or the like. These materials may be used alone or in combination with each other.

The seventh lower metal pattern 1070 and the ninth lower metal pattern 1090 may be located on the substrate SUB. In addition, a first insulating layer IL1 may be located on the substrate SUB. The first insulating layer IL1 may cover the seventh lower metal pattern 1070 and the ninth lower metal pattern 1090. For example, the first insulating layer IL1 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The fourth active pattern 2040 and the second active pattern 2020 may be located on the first insulating layer IL1. In addition, the second insulating layer IL2 may be located on the first insulating layer IL1. The second insulating layer IL2 may cover the fourth active pattern 2040 and the second active pattern 2020. For example, the second insulating layer IL2 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The fifth metal pattern 3050, the sixth metal pattern 3060, and the seventh metal pattern 3070 may be located on the second insulating layer IL2. The fifth metal pattern 3050 may be connected to the fourth active pattern 2040 through a contact hole penetrating (or, defining through) the second insulating layer IL2. In addition, the seventh metal pattern 3070 may be connected to the fourth active pattern 2040 through a contact hole penetrating (or, defining through) the second insulating layer IL2. In addition, the seventh metal pattern 3070 may be connected to the ninth lower metal pattern 1090 through a contact hole penetrating (or, defining through) the first insulating layer IL1 and the second insulating layer IL2. In addition, the seventh metal pattern 3070 may be connected to the second active pattern 2020 through a contact hole penetrating (or, defining through) the second insulating layer IL2. A third insulating layer IL3 may be located on the second insulating layer IL2. The third insulating layer IL3 may cover the fifth metal pattern 3050, the sixth metal pattern 3060, and the seventh metal pattern 3070. In one or more embodiments, the third insulating layer IL3 may include an organic material. For example, the third insulating layer IL3 may include an organic material such as a phenolic resin, an acrylic resin, a polyimide resin, a polyamide resin, a siloxane resin, an epoxy resin, and/or the like. These materials may be used alone or in combination with each other. In one or more embodiments, the third insulating layer IL3 may further include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The first light emitting element LEDa may be located on the third insulating layer IL3. For example, the first lower electrode pattern E1a may be located on the third insulating layer IL3, the first intermediate layer EMLa may be located on the first lower electrode pattern E1a, and the first upper electrode pattern E2a may be located on the first intermediate layer EMLa. In addition, the pixel defining layer PDL may be located on the third insulating layer IL3 overlapping the first lower electrode pattern Ela. As described above, the pixel defining layer PDL may define the first opening OP1 exposing a portion of the upper surface of the first lower electrode pattern E1a. The first intermediate layer EMLa and the first upper electrode pattern E2a may be located in the first opening OP1.

An encapsulation layer TFE may be located on the first upper electrode pattern E2a. For example, the encapsulation layer TFE may be located on the upper electrode layer (for example, the upper electrode layer E2 of FIG. 13). The encapsulation layer TFE may prevent impurities, moisture, and/or the like from penetrating into the first light emitting device LEDa, the second light emitting element (e.g., the second light emitting element LEDb of FIG. 13), and the third light emitting element (e.g., the third light emitting element LEDc of FIG. 13). For example, the encapsulation layer TFE may include at least one inorganic encapsulation layer and at least one organic encapsulation layer. For example, the inorganic encapsulation layer and the organic encapsulation layer may be alternately stacked. The inorganic encapsulation layer may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other. The organic encapsulation layer may include a cured polymer such as polyacrylate.

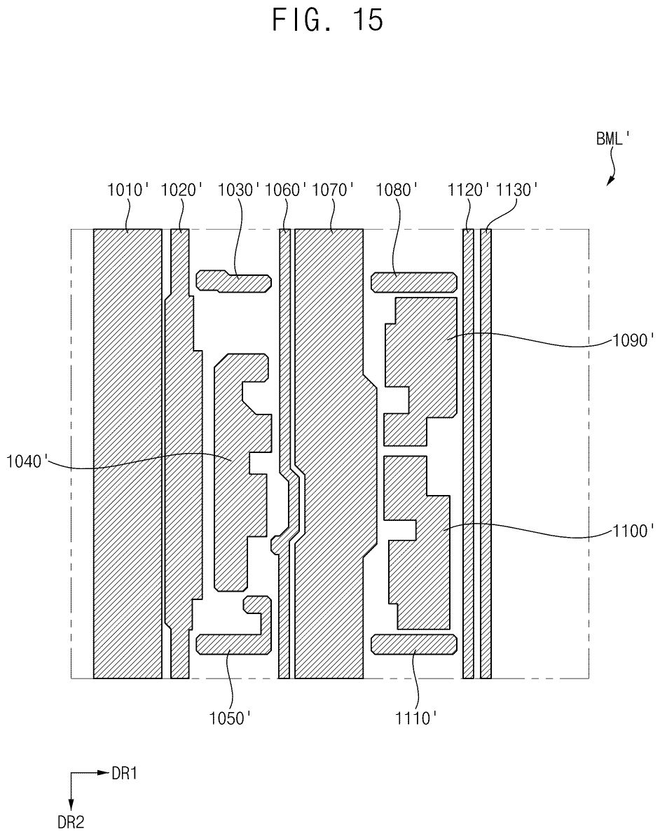

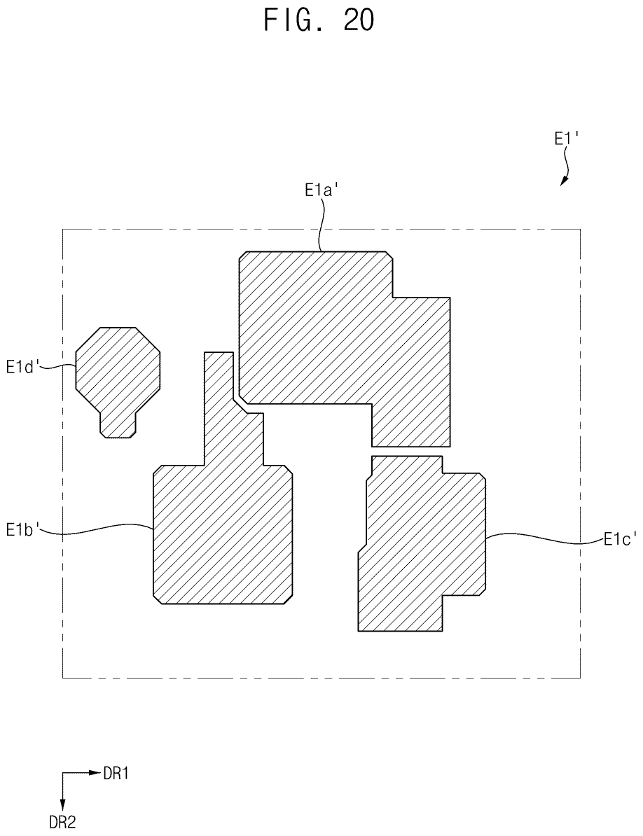

FIGS. 15, 16, 17, 18, 19, 20, 21, 22, 23, and 24 are layout views illustrating pixels included in the display device of FIG. 1 according to one or more embodiments.

Specifically, FIGS. 15, 16, 17, 18, 19, 20, 21, 22, 23, and 24 may be arrangement views illustrating the first pixel PX1, the second pixel PX2, and the third pixel PX3 of FIG. 2.

Referring to FIG. 15, the display device (for example, the display device DD of FIG. 2) may include a lower metal layer BML′. The lower metal layer BML′ may include a first lower metal pattern 1010′, a second lower metal pattern 1020′, a third lower metal pattern 1030′, a fourth lower metal pattern 1040′, a fifth lower metal pattern 1050′, a sixth lower metal pattern 1060′, a seventh lower metal pattern 1070′, an eighth lower metal pattern 1080′, a ninth lower metal pattern 1090′, a tenth lower metal pattern 1100′, an eleventh lower metal pattern 1110′, a twelfth lower metal pattern 1120′, and a thirteenth lower metal pattern 1130″.

The first lower metal pattern 1010′, the second lower metal pattern 1020′, the third lower metal pattern 1030′, the fourth lower metal pattern 1040′, the fifth lower metal pattern 1050′, the sixth lower metal pattern 1060′, the seventh lower metal pattern 1070′, the eighth lower metal pattern 1080′, the ninth lower metal pattern 1090′, the tenth lower metal pattern 1100′, the eleventh lower metal pattern 1110′, the twelfth lower metal pattern 1120′, and the thirteenth lower metal pattern 1130′ may be spaced (e.g., spaced apart) from each other in a plan view.

The first lower metal pattern 1010′ may be spaced (e.g., spaced apart) from the second lower metal pattern 1020′ in a direction opposite to the first direction DR1. The first lower metal pattern 1010′ may extend in the second direction DR2. In one or more embodiments, the second power voltage ELVSS of FIG. 3 may be applied to the first lower metal pattern 1010′. For example, the first lower metal pattern 1010′ may be at least a portion of the second voltage line VL2 of FIG. 3.

The second lower metal pattern 1020′ may be spaced (e.g., spaced apart) from the third lower metal pattern 1030′, the fourth lower metal pattern 1040′, and the fifth lower metal pattern 1050′ in a direction opposite to the first direction DR1. The second lower metal pattern 1020′ may extend in the second direction DR2. In one or more embodiments, the initialization voltage VINT of FIG. 3 may be applied to the second lower metal pattern 1020′. For example, the second lower metal pattern 1020′ may be at least a portion of the third voltage line VL3 of FIG. 3.

The third lower metal pattern 1030′ may be spaced (e.g., spaced apart) from the fourth lower metal pattern 1040′ in a direction opposite to the second direction DR2. In addition, the third lower metal pattern 1030′ may be spaced (e.g., spaced apart) from the sixth lower metal pattern 1060′ in a direction opposite to the first direction DR1.

The fourth lower metal pattern 1040′ may be spaced (e.g., spaced apart) from the fifth lower metal pattern 1050′ in a direction opposite to the second direction DR2. In addition, the fourth lower metal pattern 1040′ may be spaced (e.g., spaced apart) from the sixth lower metal pattern 1060′ in a direction opposite to the first direction DR1.

The fifth lower metal pattern 1050′ may be spaced (e.g., spaced apart) from the sixth lower metal pattern 1060′ in a direction opposite to the first direction DR1.

The sixth lower metal pattern 1060′ may be spaced (e.g., spaced apart) from the seventh lower metal pattern 1070′ in a direction opposite to the first direction DR1. The sixth lower metal pattern 1060′ may extend in the second direction DR2. In one or more embodiments, the data voltage DT of FIG. 3 may be applied to the sixth lower metal pattern 1060′. For example, a red data voltage may be applied to the sixth lower metal pattern 1060′, but the present disclosure is not limited thereto. For example, the sixth lower metal pattern 1060′ may be at least a portion of the data line DL of FIG. 3.

The seventh lower metal pattern 1070′ may be spaced (e.g., spaced apart) from the eighth lower metal pattern 1080′, the ninth lower metal pattern 1090′, the tenth lower metal pattern 1100′, and the eleventh lower metal pattern 1110′ in a direction opposite to the first direction DR1. The seventh lower metal pattern 1070′ may extend in the second direction DR2. In one or more embodiments, the first power voltage ELVDD of FIG. 3 may be applied to the seventh lower metal pattern 1070′. For example, the seventh lower metal pattern 1070′ may be at least a portion of the first voltage line VL1 of FIG. 3. For example, the seventh lower metal pattern 1070′ may be referred to as a voltage line.

The eighth lower metal pattern 1080′ may be spaced (e.g., spaced apart) from the twelfth lower metal pattern 1120′ in a direction opposite to the first direction DR1. In addition, the eighth lower metal pattern 1080′ may be spaced (e.g., spaced apart) from the ninth lower metal pattern 1090′ in a direction opposite to the second direction DR2.

The ninth lower metal pattern 1090′ may be spaced (e.g., spaced apart) from the twelfth lower metal pattern 1120′ in a direction opposite to the first direction DR1. In addition, the ninth lower metal pattern 1090′ may be spaced (e.g., spaced apart) from the tenth lower metal pattern 1100′ in a direction opposite to the second direction DR2.

The tenth lower metal pattern 1100′ may be spaced (e.g., spaced apart) from the twelfth lower metal pattern 1120′ in a direction opposite to the first direction DR1. In addition, the tenth lower metal pattern 1100′ may be spaced (e.g., spaced apart) from the eleventh lower metal pattern 1110′ in a direction opposite to the second direction DR2.

The eleventh lower metal pattern 1110′ may be spaced (e.g., spaced apart) from the twelfth lower metal pattern 1120′ in a direction opposite to the first direction DR1.

The twelfth lower metal pattern 1120′ may be spaced (e.g., spaced apart) from the thirteenth lower metal pattern 1130′ in a direction opposite to the first direction DR1. The twelfth lower metal pattern 1120′ may extend in the second direction DR2. In one or more embodiments, the data voltage DT of FIG. 3 may be applied to the twelfth lower metal pattern 1120′. For example, a blue data voltage may be applied to the twelfth lower metal pattern 1120′, but the present disclosure is not limited thereto. For example, the twelfth lower metal pattern 1120′ may be at least a portion of the data line DL of FIG. 3.

The thirteenth lower metal pattern 1130′ may extend in the second direction DR2. In one or more embodiments, the data voltage DT of FIG. 3 may be applied to the thirteenth lower metal pattern 1130′. For example, a green data voltage may be applied to the thirteenth lower metal pattern 1130′, but the present disclosure is not limited thereto. For example, the thirteenth lower metal pattern 1130′ may be at least a portion of the data line DL of FIG. 3.

For example, the lower metal layer BML′ may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

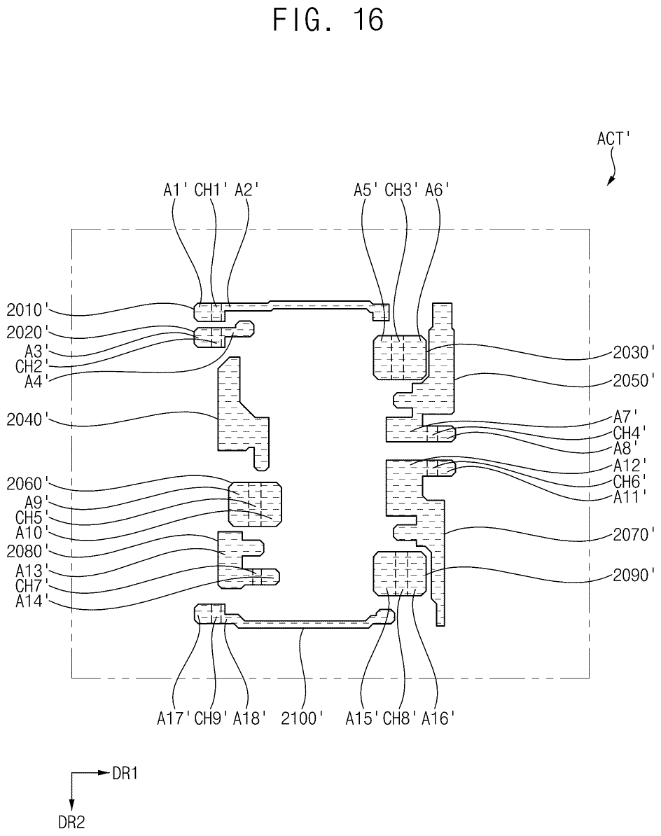

Referring to FIG. 16, an active layer ACT′ may be located on the lower metal layer (for example, the lower metal layer BML′ of FIG. 15). The active layer ACT′ may include a first active pattern 2010′, a second active pattern 2020′, a third active pattern 2030′, a fourth active pattern 2040′, a fifth active pattern 2050′, a sixth active pattern 2060′, a seventh active pattern 2070′, an eighth active pattern 2080′, a ninth active pattern 2090′, and a tenth active pattern 2100′.

The first active pattern 2010′, the second active pattern 2020′, the third active pattern 2030′, the fourth active pattern 2040′, the fifth active pattern 2050′, the sixth active pattern 2060′, the seventh active pattern 2070′, the eighth active pattern 2080′, the ninth active pattern 2090′, and the tenth active pattern 2100′ may be spaced (e.g., spaced apart) from each other in a plan view.

The first active pattern 2010′ may include a first area A1′, a first channel area CH1′, and a second area A2′. The first area A1′ and the second area A2′ may be spaced (e.g., spaced apart) from each other in a plan view. For example, the first area A1′ and the second area A2′ may be spaced (e.g., spaced apart) from each other with the first channel area CH1′ interposed therebetween. For example, the first channel area CH1′ may be located between the first area A1′ and the second area A2′. The first area A1′ and the second area A2′ may have higher conductivity than the first channel area CH1.

The second active pattern 2020′ may include a third area A3′, a second channel area CH2′, and a fourth area A4. The third area A3′ and the fourth area A4 may be spaced (e.g., spaced apart) from each other in a plan view. For example, the third area A3′ and the fourth area A4′ may be spaced (e.g., spaced apart) from each other with the second channel area CH2′ interposed therebetween. For example, the second channel area CH2′ may be located between the third area A3′ and the fourth area A4′. The third area A3′ and the fourth area A4′ may have higher conductivity than the second channel area CH2′.

In one or more embodiments, the third active pattern 2030′ may include a fifth area A5′, a sixth area A6′, and a third channel area CH3′. The fifth area A5′ and the sixth area A6′ may be spaced (e.g., spaced apart) from each other in a plan view. For example, the fifth area A5′ and the sixth area A6′ may be spaced (e.g., spaced apart) from each other with the third channel area CH3′ interposed therebetween. For example, the third channel area CH3′ may be located between the fifth area A5′ and the sixth area A6′. The fifth area A5′ and the sixth area A6′ may have higher conductivity than the third channel area CH3″.

The fourth active pattern 2040′ may include a single area. For example, the fourth active pattern 2040′ may include a single area having substantially constant conductivity over the fourth active pattern 2040′, but the present disclosure is not limited thereto.

The fifth active pattern 2050′ may include a seventh area A7′, a fourth channel area CH4′, and an eighth area A8′. The seventh area A7′ and the eighth area A8′ may be spaced (e.g., spaced apart) from each other in a plan view. For example, the seventh area A7′ and the eighth area A8′ may be spaced (e.g., spaced apart) from each other with the fourth channel area CH4 interposed therebetween. For example, the fourth channel area CH4′ may be located between the seventh area A7′ and the eighth area A8′. The seventh area A7′ and the eighth area A8′ may have higher conductivity than the fourth channel area CH4.

The sixth active pattern 2060′ may include a ninth area A9′, a fifth channel area CH5′, and a tenth area A10′. The ninth area A9′ and the tenth area A10′ may be spaced (e.g., spaced apart) from each other in a plan view. For example, the ninth area A9′ and the tenth area A10′ may be spaced (e.g., spaced apart) from each other with the fifth channel area CH5′ interposed therebetween. For example, the fifth channel area CH5′ may be located between the ninth area A9′ and the tenth area A10′. The ninth area A9′ and the tenth area A10′ may have higher conductivity than the fifth channel area CH5″.

The seventh active pattern 2070′ may include an eleventh area A11′, a sixth channel area CH6′, and a twelfth area A12′. The eleventh area A11′ and the twelfth area A12′ may be spaced (e.g., spaced apart) from each other in a plan view. For example, the eleventh area A11′ and the twelfth area A12′ may be spaced (e.g., spaced apart) from each other with the sixth channel area CH6′ interposed therebetween. For example, the sixth channel area CH6′ may be located between the eleventh area A11′ and the twelfth area A12′. The eleventh area A11′ and the twelfth area A12′ may have higher conductivity than the sixth channel area CH6′.

The eighth active pattern 2080′ may include a thirteenth area A13′, a seventh channel area CH7′, and a fourteenth area A14′. The thirteenth area A13′ and the fourteenth area A14′ may be spaced (e.g., spaced apart) from each other in a plan view. For example, the thirteenth area A13′ and the fourteenth area A14′ may be spaced (e.g., spaced apart) from each other with the seventh channel area CH7″ interposed therebetween. For example, the seventh channel area CH7′ may be located between the thirteenth area A13′ and the fourteenth area A14′. The thirteenth area A13′ and the fourteenth area A14′ may have higher conductivity than the seventh channel area CH7.

The ninth active pattern 2090′ may include a fifteenth area A15′, an eighth channel area CH8′, and a sixteenth area A16′. The fifteenth area A15′ and the sixteenth area A16′ may be spaced (e.g., spaced apart) from each other in a plan view. For example, the fifteenth area A15′ and the sixteenth area A16′ may be spaced (e.g., spaced apart) from each other with the eighth channel area CH8′ interposed therebetween. For example, the eighth channel area CH8′ may be located between the fifteenth area A15′ and the sixteenth area A16′. The fifteenth area A15′ and the sixteenth area A16′ may have higher conductivity than the eighth channel area CH8″.

The tenth active pattern 2100′ may include a seventeenth area A17, a ninth channel area CH9′, and an eighteenth area A18′. The seventeenth area A17′ and the eighteenth area A18′ may be spaced (e.g., spaced apart) from each other in a plan view. For example, the seventeenth area A17′ and the eighteenth area A18′ may be spaced (e.g., spaced apart) from each other with the ninth channel area CH9′ interposed therebetween. For example, the ninth channel area CH9′ may be located between the seventeenth area A17 and the eighteenth area A18′. The seventeenth area A17′ and the eighteenth area A18′ may have higher conductivity than the ninth channel area CH9′.

For example, the active layer ACT′ may include an inorganic semiconductor (e.g., amorphous silicon, polysilicon, a metal oxide semiconductor), an organic semiconductor, and/or the like. These materials may be used alone or in combination with each other. The active layer ACT may include a source area, a drain area, and a channel area located between the source area and the drain area. The metal oxide semiconductor may include a binary compound (“ABₓ”), a ternary compound (“ABₓC_{y}”), a quaternary compound (“ABₓC_{y}D_{z}”), or the like including indium (“In”), zinc (“Zn”), gallium (“Ga”), tin (“Sn”), titanium (“Ti”), aluminum (“Al”), hafnium (“Hf”), zirconium (“Zr”), magnesium (“Mg”), and/or the like. These materials may be used alone or in combination with each other. For example, the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), and/or indium gallium zinc oxide (“IGZO”). These materials may be used alone or in combination with each other.

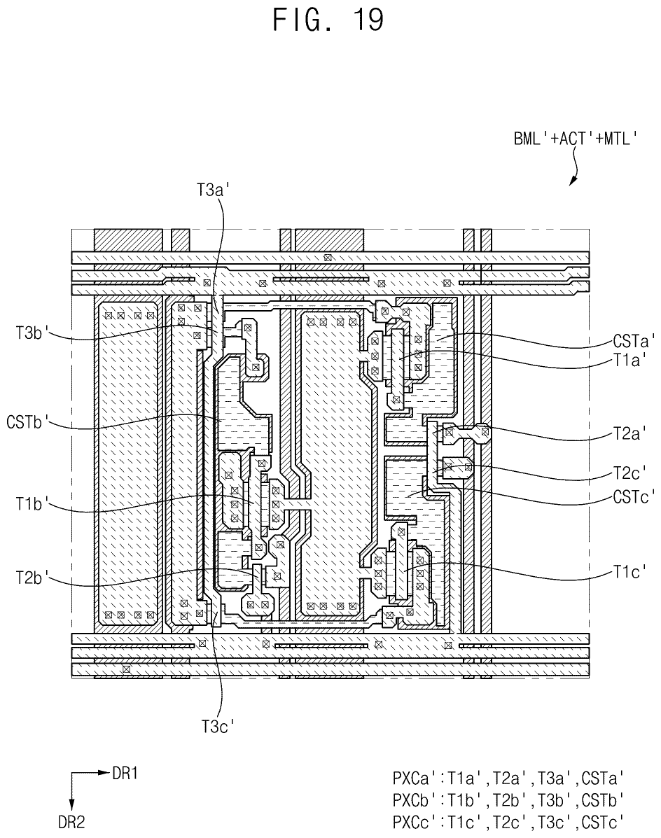

Referring to FIGS. 15, 16, and 17, a capacitor CSTa′ may include a portion of the ninth lower metal pattern 1090′ and a portion of the fifth active pattern 2050. For example, the capacitor CSTa′ may include a portion of the seventh area A7′ and the portion of the ninth lower metal pattern 1090′. The portion of the seventh area A7′ and the portion of the ninth lower metal pattern 1090′ may overlap each other in a plan view. The capacitor CSTa′ may be a capacitor included in a first pixel driving circuit portion PXCa′ of FIG. 19.

A capacitor CSTb′ may include a portion of the fourth lower metal pattern 1040′ and a portion of the fourth active pattern 2040′. The portion of the fourth lower metal pattern 1040′ and the portion of the fourth active pattern 2040′ may overlap each other in a plan view. The capacitor CSTb′ may be a capacitor included in a second pixel driving circuit portion PXCb′ of FIG. 19.

A capacitor CSTc′ may include a portion of the tenth lower metal pattern 1100′ and a portion of the seventh active pattern 2070′. For example, the capacitor CSTc′ may include a portion of the twelfth area A12′ of the seventh active pattern 2070′ and the portion of the tenth lower metal pattern 1100′. The portion of the twelfth area A12′ and the portion of the tenth lower metal pattern 1100′ may overlap each other in a plan view. The capacitor CSTc′ may be a capacitor included in a third pixel driving circuit portion PXCc′ of FIG. 19.

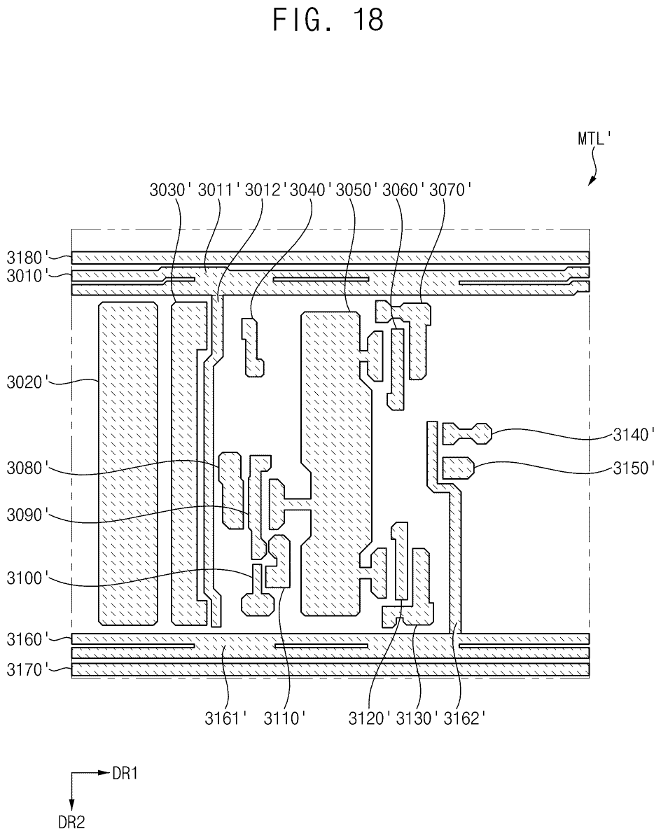

Referring to FIG. 18, a metal layer MTL′ may be located on the active layer (for example, the active layer ACT of FIG. 16). The metal layer MTL′ may include a first metal pattern 3010′, a second metal pattern 3020′, a third metal pattern 3030′, a fourth metal pattern 3040′, a fifth metal pattern 3050′, a sixth metal pattern 3060′, a seventh metal pattern 3070′, an eighth metal pattern 3080′, a ninth metal pattern 3090′, a tenth metal pattern 3100′, an eleventh metal pattern 3110′, a twelfth metal pattern 3120′, a thirteenth metal pattern 3130′, a fourteenth metal pattern 3140′, a fifteenth metal pattern 3150′, a sixteenth metal pattern 3160′, a seventeenth metal pattern 3170′, and an eighteenth metal pattern 3180′.

The first metal pattern 3010′, the second metal pattern 3020′, the third metal pattern 3030′, the fourth metal pattern 3040′, the fifth metal pattern 3050′, the sixth metal pattern 3060′, the seventh metal pattern 3070′, the eighth metal pattern 3080′, the ninth metal pattern 3090′, the tenth metal pattern 3100′, the eleventh metal pattern 3110′, the twelfth metal pattern 3120′, the thirteenth metal pattern 3130′, the fourteenth metal pattern 3140′, the fifteenth metal pattern 3150′, the sixteenth metal pattern 3160′, the seventeenth metal pattern 3170′, and the eighteenth metal pattern 3180′ may be spaced (e.g., spaced apart) from each other in a plan view.

In one or more embodiments, the first metal pattern 3010′ may include a first portion 3011′ and a second portion 3012′. The first portion 3011′ may extend in the first direction DR1. The second portion 3012′ may be a portion extending from the first portion 3011. For example, the second portion 3012′ may be a portion extending in the second direction DR2 from the first portion 3011′. In one or more embodiments, the sensing signal SS of FIG. 3 may be applied to the first metal pattern 3010′. For example, the first metal pattern 3010′ may be at least a portion of the sensing signal line SSL of FIG. 3.

The second metal pattern 3020′ may be located between a first portion 3011′ of the first metal pattern 3010′ and a first portion 3161′ of the sixteenth metal pattern 3160′ to be described later. In addition, the second metal pattern 3020′ may be spaced (e.g., spaced apart) from the third metal pattern 3030′ in a direction opposite to the first direction DR1. The second metal pattern 3020′ may extend in the second direction DR2.

The third metal pattern 3030′ may be spaced (e.g., spaced apart) from the first portion 3011′ of the first metal pattern 3010′ in the second direction DR2. In addition, the third metal pattern 3030′ may be spaced (e.g., spaced apart) from the second portion 3012′ of the first metal pattern 3010′ in a direction opposite to the first direction DR1. In addition, the third metal pattern 3030′ may be spaced (e.g., spaced apart) from the first portion 3161′ of the sixteenth metal pattern 3160′ in a direction opposite to the second direction DR2. The third metal pattern 3030′ may extend in the second direction DR2.

The fourth metal pattern 3040′ may be spaced (e.g., spaced apart) from the first portion 3011′ of the first metal pattern 3010′ in the second direction DR2. In addition, the fourth metal pattern 3040′ may be spaced (e.g., spaced apart) from the second portion 3012′ of the first metal pattern 3010′ in the first direction DR1. In addition, the fourth metal pattern 3040′ may be spaced (e.g., spaced apart) from the fifth metal pattern 3050′ in a direction opposite to the first direction DR1.

The fifth metal pattern 3050′ may be spaced (e.g., spaced apart) from the first portion 3011′ of the first metal pattern 3010′ in the second direction DR2. In addition, the fifth metal pattern 3050′ may be spaced (e.g., spaced apart) from the first portion 3161′ of the sixteenth metal pattern 3160′ in a direction opposite to the second direction DR2. In addition, the fifth metal pattern 3050′ may be spaced (e.g., spaced apart) from the sixth metal pattern 3060′ and the twelfth metal pattern 3120′ in a direction opposite to the first direction DR1. The fifth metal pattern 3050′ may extend in the second direction DR2.

The sixth metal pattern 3060′ may be spaced (e.g., spaced apart) from the twelfth metal pattern 3120′ in a direction opposite to the second direction DR2.

The seventh metal pattern 3070′ may be spaced (e.g., spaced apart) from the first portion 3011′ of the first metal pattern 3010′ in the second direction DR2.

The eighth metal pattern 3080′ may be spaced (e.g., spaced apart) from the second portion 3012′ of the first metal pattern 3010′ in the first direction DR1. In addition, the eighth metal pattern 3080′ may be spaced (e.g., spaced apart) from the ninth metal pattern 3090′ in a direction opposite to the first direction DR1.

The ninth metal pattern 3090′ may be spaced (e.g., spaced apart) from the fifth metal pattern 3050′ in a direction opposite to the first direction DR1. In addition, the ninth metal pattern 3090′ may be spaced (e.g., spaced apart) from the tenth metal pattern 3100′ in a direction opposite to the second direction DR2. In addition, the ninth metal pattern 3090′ may be spaced (e.g., spaced apart) from the fourth metal pattern 3040′ in the second direction DR2.

The tenth metal pattern 3100′ may be spaced (e.g., spaced apart) from the eleventh metal pattern 3110′ in a direction opposite to the first direction DR1. In addition, the tenth metal pattern 3100′ may be spaced (e.g., spaced apart) from the first portion 3161′ of the sixteenth metal pattern 3160′ in a direction opposite to the second direction DR2.

The eleventh metal pattern 3110′ may be spaced (e.g., spaced apart) from the first portion 3161′ of the sixteenth metal pattern 3160′ in a direction opposite to the second direction DR2.

The twelfth metal pattern 3120′ may be spaced (e.g., spaced apart) from the sixth metal pattern 3060′ in the second direction DR2.

The thirteenth metal pattern 3130′ may be spaced (e.g., spaced apart) from the first portion 3161′ of the sixteenth metal pattern 3160′ in a direction opposite to the second direction DR2. In addition, the thirteenth metal pattern 3130′ may be spaced (e.g., spaced apart) from a second portion 3162′ of the sixteenth metal pattern 3160′, to be described later, in a direction opposite to the first direction DR1.

The fourteenth metal pattern 3140′ may be spaced (e.g., spaced apart) from the second portion 3162′ of the sixteenth metal pattern 3160′ in the first direction DR1. In addition, the fourteenth metal pattern 3140′ may be spaced (e.g., spaced apart) from the fifteenth metal pattern 3150′ in a direction opposite to the second direction DR2.

The fifteenth metal pattern 3150′ may be located adjacent to the second portion 3162′ of the sixteenth metal pattern 3160′.

In one or more embodiments, the sixteenth metal pattern 3160′ may include a first portion 3161′ and a second portion 3162′. The first portion 3161′ may extend in the first direction DR1. The second portion 3162′ may extend from the first portion 3161′. For example, the second portion 3162′ may be a portion extending from the first part 3161′ in a direction opposite to the second direction DR2. In one or more embodiments, the scan signal SC of FIG. 3 may be applied to the sixteenth metal pattern 3160′. For example, the sixteenth metal pattern 3160′ may be at least a portion of the scan signal line SCL of FIG. 3.

The seventeenth metal pattern 3170′ may be spaced (e.g., spaced apart) from the sixteenth metal pattern 3160′ in the second direction DR2. The seventeenth metal pattern 3170′ may extend in the first direction DR1.

The eighteenth metal pattern 3180′ may be spaced (e.g., spaced apart) from the first metal pattern 3010′ in a direction opposite to the second direction DR2. For example, the eighteenth metal pattern 3180′ may be spaced (e.g., spaced apart) from the first portion 3011′ of the first metal pattern 3010′ in a direction opposite to the second direction DR2. The eighteenth metal pattern 3180′ may extend in the first direction DR1.

For example, the metal layer MTL′ may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

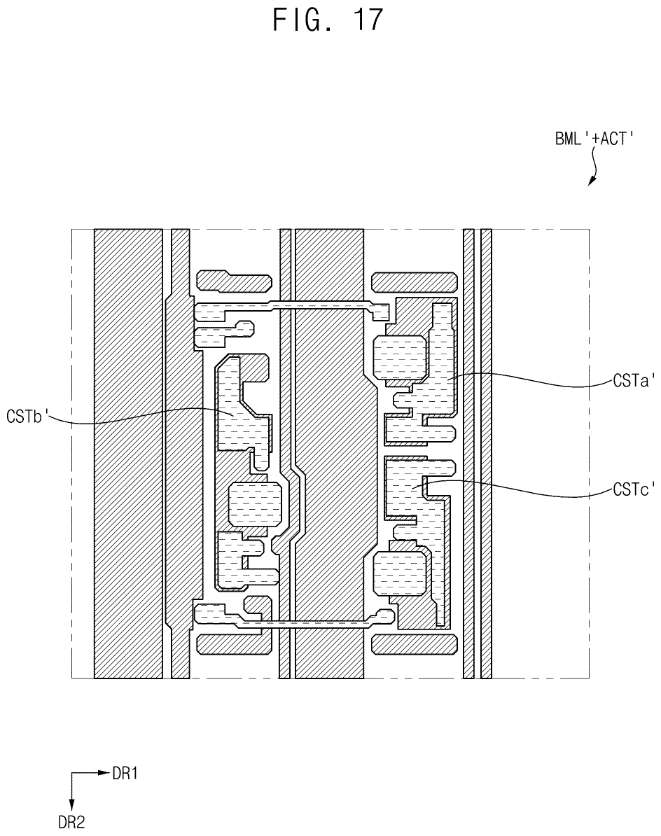

Referring to FIGS. 17, 18, and 19 a portion of the metal layer MTL′ may be connected to a portion of the lower metal layer BML′ through a contact hole. In addition, a portion of the metal layer MTL′ may be connected to a portion of the active layer ACT′ through a contact hole. As illustrated in FIG. 19, the contact hole is indicated by an “X” in a square box.

In one or more embodiments, the display device (e.g., the display device DD of FIG. 2) may include a first pixel driving circuit portion PXCa′, a second pixel driving circuit portion PXCb′, and a third pixel driving circuit portion PXCc′. For example, the first pixel driving circuit portion PXCa′ is included in the first pixel PX1 of FIG. 2, the second pixel driving circuit portion PXCb′ is included in the second pixel PX2 of FIG. 2, and the third pixel driving circuit portion PXCc′ may be included in the third pixel PX3 of FIG. 2, but the present disclosure is not limited thereto. In addition, each of the first pixel driving circuit portion PXCa′, the second pixel driving circuit portion PXCb′, and the third pixel driving circuit portion PXCc′ may have substantially same structure as the pixel driving circuit portion PXC of FIG. 3, but the present disclosure is not limited thereto.

The first pixel driving circuit portion PXCa′ may include a first transistor T1a′, a second transistor T2a′, a third transistor T3a′, and a capacitor CSTa′. The first transistor T1a′ may correspond to the first transistor T1 of FIG. 3, the second transistor T2a′ may correspond to the second transistor T2 of FIG. 3, the third transistor T3a′ may correspond to the third transistor T3 of FIG. 3, and the capacitor CSTa′ may correspond to the capacitor CST of FIG. 3.

The second pixel driving circuit portion PXCb′ may include a first transistor T1b′, a second transistor T2b′, a third transistor T3b′, and a capacitor CSTb′. The first transistor T1b′ may correspond to the first transistor T1 of FIG. 3, the second transistor T2b′ may correspond to the second transistor T2 of FIG. 3, the third transistor T3b may correspond to the third transistor T3 of FIG. 3, and the capacitor CSTb′ may correspond to the capacitor CST of FIG. 3.

The third pixel driving circuit portion PXCc′ may include a first transistor T1c′, a second transistor T2c′, a third transistor T3c′, and a capacitor CSTc′. The first transistor T1c′ may correspond to the first transistor T1 of FIG. 3, the second transistor T2c′ may correspond to the second transistor T2 of FIG. 3, the third transistor T3c may correspond to the third transistor T3 of FIG. 3, and the capacitor CSTc′ may correspond to the capacitor CST of FIG. 3.

The first transistor T1a′ may include a portion of the third active pattern 2030′ (i.e., a portion of the fifth area A5′, a portion of the sixth area A6′, and the third channel area CH3′), and a portion of the sixth metal pattern 3060′ overlapping the third channel area CH3′ in a plan view. For example, the portion of the sixth metal pattern 3060′ overlapping the third channel area CH3′ in a plan view may be referred to as a gate electrode of the first transistor T1a.

The second transistor T2a′ may include a portion of the fifth active pattern 2050′ (i.e., a portion of the seventh area A7′, a portion of the eighth area A8′, and the fourth channel area CH4), and a portion of the second portion 3162′ of the sixth metal pattern 3060′ overlapping the fourth channel area CH4′ in a plan view. For example, the portion of the second portion 3162′ of the sixth metal pattern 3060′ overlapping the fourth channel area CH4′ in a plan view may be referred to as the gate electrode of the second transistor T2a′.

The third transistor T3a′ may include a portion of the first active pattern 2010′ (i.e., a portion of the first area A1, a portion of the second area A2′, and the first channel area CH1′), and a portion of the second portion 3012′ of the first metal pattern 3010 overlapping the first channel area CH1′ in a plan view. For example, the portion of the second portion 3012′ of the first metal pattern 3010 overlapping the first channel area CH1′ in a plan view may be referred to as a gate electrode of the third transistor T3a.

The first transistor T1b′ may include a portion of the sixth active pattern 2060′ (i.e., a portion of the ninth area A9′, a portion of the tenth area A10′, and the fifth channel area CH5′), and a portion of the ninth metal pattern 3090′ overlapping the fifth channel area CH5′ in a plan view. For example, the portion of the ninth metal pattern 3090′ overlapping the fifth channel area CH5′ in a plan view may be referred to as a gate electrode of the first transistor T1b′.

The second transistor T2b′ may include a portion of the eighth active pattern 2080′ (i.e., a portion of the thirteenth area A13′, a portion of the fourteenth area A14′, and the seventh channel area CH7), and a portion of the tenth metal pattern 3100′ overlapping the seventh channel area CH7′ in a plan view. For example, the portion of the tenth metal pattern 3100′ overlapping the seventh channel area CH7′ in a plan view may be referred to as a gate electrode of the second transistor T2b″.

The third transistor T3b′ may include a portion of the second active pattern 2020′ (i.e., a portion of the third area A3′, a portion of the fourth area A4, and the second channel area CH2′), and a portion of the second portion 3012′ of the first metal pattern 3010 overlapping the second channel area CH2′ in a plan view. For example, the portion of the second portion 3012′ overlapping the second channel area CH2′ in a plan view may be referred to as a gate electrode of the third transistor T3b″.

The first transistor T1c′ may include a portion of the ninth active pattern 2090′ (i.e., a portion of the fifteenth area A15′, a portion of the sixteenth area A16′, and an eighth channel area CH8′), and a portion of the twelfth metal pattern 3120′ overlapping the eighth channel area CH8′ in a plan view. For example, the portion of the twelfth metal pattern 3120′ overlapping the eighth channel area CH8′ in a plan view may be referred to as a gate electrode of the first transistor T1c.

The second transistor T2c′ may include a portion of the seventh active pattern 2070′ (i.e., a portion of the eleventh area A11′, a portion of the twelfth area A12′, and the sixth channel area CH6′), and a portion of the second portion 3162′ of the sixteenth metal pattern 3160′ overlapping the sixth channel area CH6′ in a plan view. For example, the portion of the second portion 3162′ overlapping the sixth channel area CH6′ in a plan view may be referred to as a gate electrode of the second transistor T2c.

The third transistor T3c′ may include a portion of the tenth active pattern 2100′ (i.e., a portion of the seventeenth area A17′, a portion of the eighteenth area A18′, and the ninth channel area CH9′) and a portion of the second portion 3012′ overlapping the ninth channel area CH9′ in a plan view. For example, the portion of the second portion 3012′ of the first metal pattern 3010 overlapping the ninth channel area CH9′ in a plan view may be referred to as a gate electrode of the third transistor T3c.

Referring further to FIG. 15, in one or more embodiments, the first transistor T1a′ may be located at one side of the seventh lower metal pattern 1070′. For example, the first transistor T1a′ may be spaced (e.g., spaced apart) from the seventh lower metal pattern 1070′ in the first direction DR1. In addition, the first transistor T1b′ may be located at other side of the seventh lower metal pattern 1070′. For example, the first transistor T1b′ may be spaced (e.g., spaced apart) from the seventh lower metal pattern 1070 in a direction opposite to the first direction DR1. In addition, the first transistor T1c′ may be located at one side of the seventh lower metal pattern 1070″. For example, the first transistor T1c′ may be spaced (e.g., spaced apart) from the seventh lower metal pattern 1070′ in the first direction DR1. As described above, the first power voltage ELVDD of FIG. 3 may be applied to the seventh lower metal pattern 1070′, and the seventh lower metal pattern 1070′ may be referred to as the voltage line. Each of the first transistor T1a′ and the first transistor T1c′ may be located at one side of the voltage line, and the first transistor T1b′ may be located at other side of the voltage line.

In one or more embodiments, the second transistor T2a′ may be located at one side of the seventh lower metal pattern 1070′. For example, the second transistor T2a′ may be spaced (e.g., spaced apart) from the seventh lower metal pattern 1070′ in the first direction DR1. In addition, the second transistor T2b′ may be located at other side of the seventh lower metal pattern 1070′. For example, the second transistor T2b′ may be spaced (e.g., spaced apart) from the seventh lower metal pattern 1070′ in a direction opposite to the first direction DR1. In addition, the second transistor T2c′ may be located at one side of the seventh lower metal pattern 1070′. For example, the second transistor T2c′ may be spaced (e.g., spaced apart) from the seventh lower metal pattern 1070′ in the first direction DR1. Each of the second transistor T2a′ and the second transistor T2c′ may be located at one side of the voltage line, and the second transistor T2b′ may be located at other side of the voltage line.

In one or more embodiments, the third transistor T3a′ may be located at other side of the seventh lower metal pattern 1070′. For example, the third transistor T3a′ may be spaced (e.g., spaced apart) from the seventh lower metal pattern 1070′ in a direction opposite to the first direction DR1. In addition, the third transistor T3b′ may be located at other side of the seventh lower metal pattern 1070′. For example, the third transistor T3b′ may be spaced (e.g., spaced apart) from the seventh lower metal pattern 1070′ in a direction opposite to the first direction DR1. In addition, the third transistor T3c′ may be located at other side of the seventh lower metal pattern 1070′. For example, the third transistor T3c′ may be spaced (e.g., spaced apart) from the seventh lower metal pattern 1070′ in a direction opposite to the first direction DR1. Each of the third transistor T3a′, the third transistor T3b′, and the third transistor T3c′ may be located at other side of the voltage line.

In one or more embodiments, the capacitor CSTa′ may be located at one side of the seventh lower metal pattern 1070′. For example, the capacitor CSTa′ may be spaced (e.g., spaced apart) from the seventh lower metal pattern 1070′ in the first direction DR1. In addition, the capacitor CSTb′ may be located at other side of the seventh lower metal pattern 1070′. For example, the capacitor CSTb′ may be spaced (e.g., spaced apart) from the seventh lower metal pattern 1070′ in a direction opposite to the first direction DR1. In addition, the capacitor CSTc′ may be located at one side of the seventh lower metal pattern 1070′. For example, the capacitor CSTc′ may be spaced (e.g., spaced apart) from the seventh lower metal pattern 1070′ in the first direction DR1. Each of the capacitor CSTa′ and the capacitor CSTc′ may be located at one side of the voltage line, and the capacitor CSTb′ may be located at the other side of the voltage line.

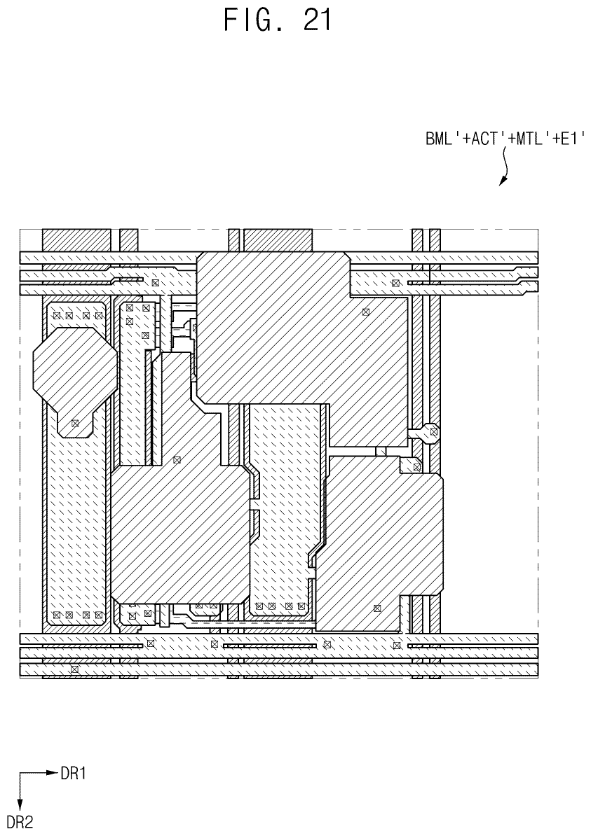

Referring to FIGS. 19, 20, and 21, a lower electrode layer E1′ may be located on the metal layer MTL′. The lower electrode layer E1′ may include a first lower electrode pattern Ela′, a second lower electrode pattern E1b′, a third lower electrode pattern E1c′, and a fourth lower electrode pattern E1d′. The first lower electrode pattern E1a′, the second lower electrode pattern E1b′, the third lower electrode pattern E1c′, and the fourth lower electrode pattern E1d′ may be spaced (e.g., spaced apart) from each other in a plan view. For example, the lower electrode layer E1′ may have a stacked structure including ITO/Ag/ITO, but the present disclosure is not limited thereto. A portion of the lower electrode layer E1′ may be connected to a portion of the metal layer MTL′ through a contact hole. As illustrated in FIG. 21, the contact hole is indicated by an “X” in a square box.

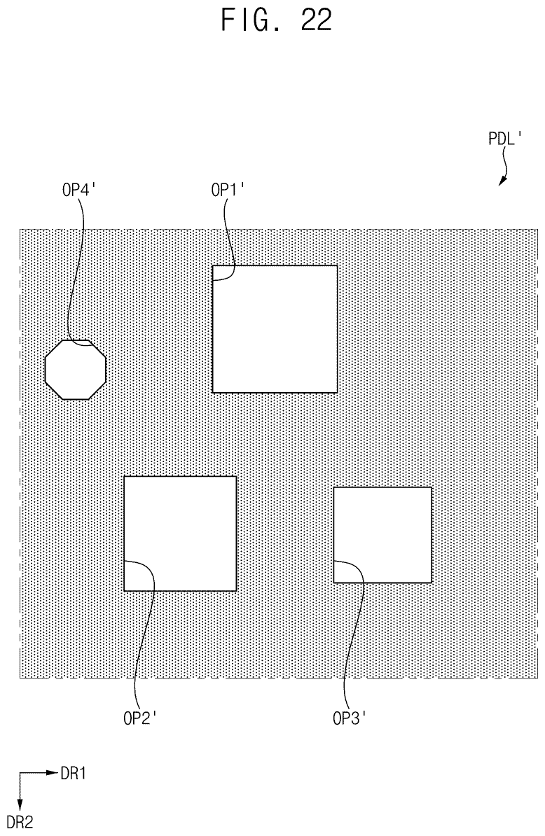

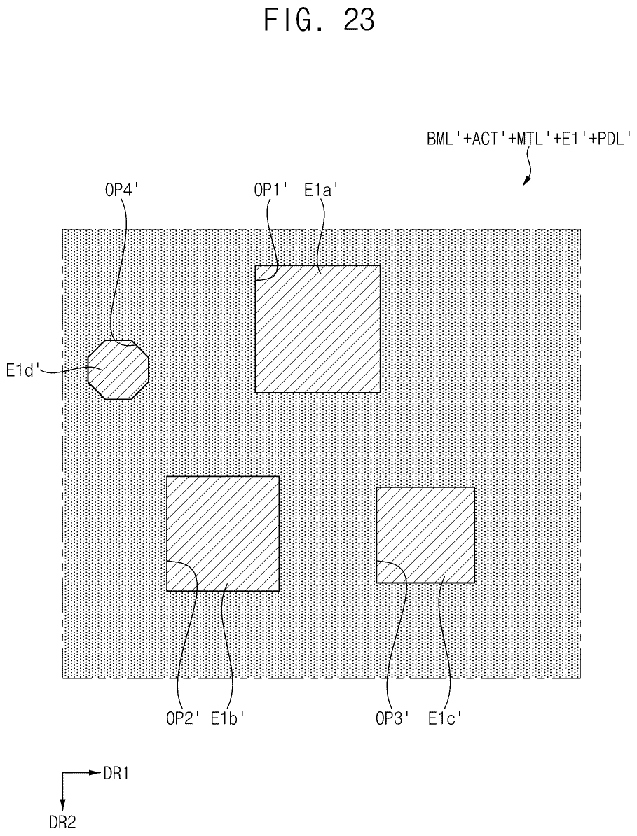

Referring to FIGS. 22 and 23, a pixel defining layer PDL′ may be located on the lower electrode layer E1′. For example, the pixel defining layer PDL′ may cover the lower electrode layer E1′. In one or more embodiments, the pixel defining layer PDL may define a first opening OP1′, a second opening OP2′, a third opening OP3′, and a fourth opening OP4′. The first opening OP1′ may expose at least a portion of an upper surface of the first lower electrode pattern Ela′. In addition, the second opening OP2′ may expose at least a portion of an upper surface of the second lower electrode pattern E1b′. In addition, the third opening OP3′ may expose at least a portion of an upper surface of the third lower electrode pattern E1c′. In addition, the fourth opening OP4′ may expose at least a portion of an upper surface of the fourth lower electrode pattern E1d′. The first opening OP1′, the second opening OP2′, the third opening OP3′ and the fourth opening OP4′ may be spaced (e.g., spaced apart) from each other in a plan view.

For example, the pixel defining layer PDL′ may include an inorganic material and/or an organic material. In one or more embodiments, the pixel defining layer PDL′ may include an organic material such as an epoxy resin, a siloxane resin, and/or the like. These materials may be used alone or in combination with each other. In one or more embodiments, the pixel defining layer PDL′ may further include a light blocking material including a black pigment and/or a black dye.

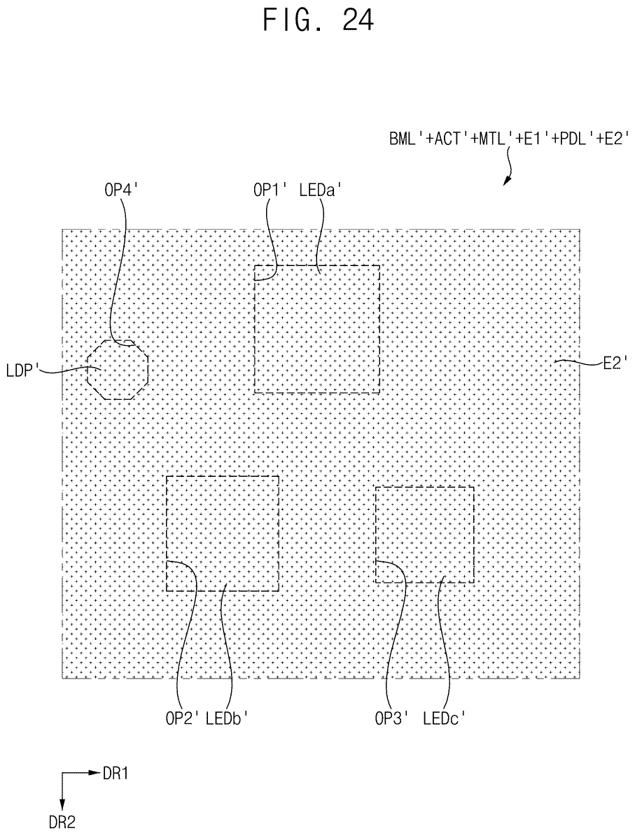

Referring to FIGS. 23 and 24, an upper electrode layer E2′ may be located on the pixel defining layer PDL′ and the lower electrode layer E1′. In one or more embodiments, the upper electrode layer E2′ may be located over the entire display area (e.g., the display area DA of FIG. 2). For example, a portion of the upper electrode layer E2′ located in the first opening OP1′ may be referred to as a first upper electrode pattern, and a portion of the upper electrode layer E2′ located in the second opening OP2′ may be referred to as a second upper electrode pattern, and a portion of the upper electrode layer E2′ located in the third opening OP3′ may be referred to as a third upper electrode pattern, and a portion of the upper electrode layer E2′ located in the fourth opening OP4′ may be referred to as a fourth upper electrode pattern.

For example, the upper electrode layer E2′ may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

A first light emitting element LEDa′ may be located in the first opening OP1″. The first light emitting element LEDa′ may be included in the first pixel PX1 of FIG. 2. For example, the first pixel PX1 of FIG. 2 may include the first light emitting element LEDa′ and the first pixel driving circuit portion (e.g., the first pixel driving circuit portion PXCa′ of FIG. 19) electrically connected to the first light emitting element LEDa ′.

The first light emitting element LEDa may include a first lower metal pattern Ela′, a first intermediate layer, and the first upper metal pattern. The first intermediate layer may be located between the first lower metal pattern Ela′ and the first upper metal pattern. The first lower metal pattern Ela′ may be an anode of the first light emitting element LEDa′, and the first upper metal pattern may be a cathode of the first light emitting element LEDa′.

The second light emitting element LEDb′ may be located in the second opening OP2′. The second light emitting element LEDb′ may be included in the second pixel PX2 of FIG. 2. For example, the second pixel PX2 of FIG. 2 may include the second light emitting element LEDb′ and the second pixel driving circuit portion (for example, the second pixel driving circuit portion PXCb′ of FIG. 19) electrically connected to the second light emitting element LEDb′.

The second light emitting element LEDb′ may include the second lower metal pattern E1b′, a second intermediate layer, and the second upper metal pattern. The second intermediate layer may be located between the second lower metal pattern E1b′ and the second upper metal pattern. The second lower metal pattern E1b′ may be an anode of the second light emitting element LEDb′, and the second upper metal pattern may be a cathode of the second light emitting element LEDb′.

The third light emitting element LEDc′ may be located in the third opening OP3′. The third light emitting element LEDc′ may be included in the third pixel PX3 of FIG. 2. For example, the third pixel PX3 of FIG. 2 may include the third light emitting element LEDc′ and the third pixel driving circuit portion (for example, the third pixel driving circuit portion PXCc′ of FIG. 19) electrically connected to the third light emitting element LEDc′.

The third light emitting element LEDc′ may include the third lower metal pattern E1c′, a third intermediate layer, and the third upper metal pattern. The third intermediate layer may be located between the third lower metal pattern E1c′ and the third upper metal pattern. The third lower metal pattern E1c′ may be an anode of the third light emitting element LEDc′, and the third upper metal pattern may be a cathode of the third light emitting element LEDc′.

In one or more embodiments, each of the first intermediate layer, the second intermediate layer, and the third intermediate layer may include a first functional layer, a light emitting layer located on the first functional layer, and a second functional layer located on the light emitting layer. For example, the first functional layer may include a hole injection layer, a hole transport layer, and/or the like, and the second functional layer may include an electron transport layer, an electron injection layer, and/or the like. The first intermediate layer, the second intermediate layer, and the third intermediate layer may not be shown in FIGS. 15, 16, 17, 18, 19, 20, 21, 22, 23, and 24.

In one or more embodiments, the first light emitting element LEDa′, the second light emitting element LEDb′, and the third light emitting element LEDc′ may emit light having different wavelengths from each other. For example, the first light emitting element LEDa′ may emit green light, the second light emitting element LEDb′ may emit red light, and the third light emitting element LEDc′ may emit blue light, but the present disclosure is not limited thereto. In one or more embodiments, the first light emitting element LEDa′, the second light emitting element LEDb′, and the third light emitting element LEDc′ may be spaced (e.g., spaced apart) from each other in a plan view.

A contact portion LDP′ may be located in the fourth opening OP4. The contact portion LDP′ may be a portion where the fourth lower electrode pattern E1d′ and the fourth upper electrode pattern contact with each other through the fourth opening OP4′. The fourth lower electrode pattern E1d′ may be connected to the first lower metal pattern 1010′ of FIG. 15 through a contact hole. The second power voltage ELVSS of FIG. 3 may be applied to the first lower metal pattern 1010′ of FIG. 15. For example, in the fourth opening OP4′, the fourth upper electrode pattern may be connected to the first lower metal pattern 1010′ of FIG. 15 through the fourth lower electrode pattern E1d′. Accordingly, an IR-drop phenomenon of the upper electrode layer E2′ may be prevented.

Referring further to FIGS. 19 and 24, each of the first light emitting element LEDa′, the second light emitting element LEDb′, and the third light emitting element LEDc′ may emit light in all directions. For example, light emitted from the first light emitting element LEDa′ may reach the second pixel driving circuit portion PXCb′ and the third pixel driving circuit portion PXCc′. In addition, light emitted from the second light emitting element LEDb′ may reach the first pixel driving circuit portion PXCa′ and the third pixel driving circuit portion PXCc′. In addition, light emitted from the third light emitting element LEDc′ may reach the first pixel driving circuit portion PXCa′ and the second pixel driving circuit portion PXCb′.

In one or more embodiments, the first transistor T1a′ may at least partially overlap the first light emitting element LEDa′ in a plan view. In addition, the first transistor T1b′ may at least partially overlap the second light emitting element LEDb′ in a plan view. In addition, the first transistor T1c′ may at least partially overlap the third light emitting element LEDc′ in a plan view. Accordingly, a sufficient separation distance in a plan view between the first transistor T1a′ and the second light emitting element LEDb′ may be secured. In addition, a sufficient separation distance in a plan view between the first transistor T1a′ and the third light emitting element LEDc′ may be secured. Accordingly, light emitted from each of the second light emitting element LEDb′ and the third light emitting element LEDc′ may be prevented from reaching the first transistor T1a′. Alternatively, only a small portion of the light emitted from each of the second light emitting element LEDb′ and the third light emitting element LEDc′ may reach the first transistor T1a′. Accordingly, deterioration of the first transistor T1a′ may be prevented or reduced.

In addition, a sufficient separation distance in a plan view between the first transistor T1b′ and the first light emitting element LEDa′ may be secured. In addition, a sufficient separation distance in a plan view between the first transistor T1b′ and the third light emitting element LEDc′ may be secured. Accordingly, light emitted from each of the first light emitting element LEDa′ and the third light emitting element LEDc′ may be prevented from reaching the first transistor T1b′. Alternatively, only a small portion of the light emitted from each of the first light emitting element LEDa′ and the third light emitting element LEDc′ may reach the first transistor T1b′. Accordingly, deterioration of the first transistor T1b′ may be prevented or reduced.

In addition, a sufficient separation distance in a plan view between the first transistor T1c′ and the first light emitting element LEDa′ may be secured. In addition, a sufficient separation distance in a plan view between the first transistor T1c′ and the second light emitting element LEDb′ may be secured. Accordingly, light emitted from each of the first light emitting element LEDa′ and the second light emitting element LEDb′ may be prevented from reaching the first transistor T1c′. Alternatively, only a small portion of the light emitted from each of the first light emitting element LEDa′ and the second light emitting element LEDb′ may reach the first transistor T1c′. Accordingly, deterioration of the first transistor T1c′ may be prevented or reduced.

For example, the first transistor T1a′ may not be affected by light emitted from light emitting elements adjacent to the first transistor T1a′. In addition, the first transistor T1b′ may not be affected by light emitted from light emitting elements adjacent to the first transistor T1b′. In addition, the first transistor T1c′ may not be affected by light emitted from light emitting elements adjacent to the first transistor T1c.

In addition, as described above, each of the first transistor T1a′ and the first transistor T1c′ may be located at one side of the voltage line, and the first transistor T1b′ may be located at other side of the voltage line. Accordingly, a sufficient separation distance in a plan view between the first transistor T1a′ and the second light emitting element LEDb′ may be secured. In addition, a sufficient separation distance in a plan view between the first transistor T1b′ and the first light emitting element LEDa′ may be secured. In addition, a sufficient separation distance in a plan view between the first transistor T1b′ and the third light emitting element LEDc′ may be secured. In addition, a sufficient separation distance in a plan view between the first transistor T1c′ and the second light emitting element LEDb′ may be secured. Accordingly, deterioration of each of the first transistor T1a′, the first transistor T1b′, and the first transistor T1c′ may be prevented or reduced.

In addition, as described above, each of the second transistor T2a′ and the second transistor T2c′ may be located at one side of the voltage line, and the second transistor T2b′ may be located at other side of the voltage line. Accordingly, a separation distance in a plan view between the second transistor T2a′ and the second light emitting element LEDb′ may be secured. Accordingly, light emitted from the second light emitting element LEDb′ may be prevented from reaching the second transistor T2a′. Accordingly, deterioration of the second transistor T2a′ may be prevented or reduced. In addition, a separation distance in a plan view between the second transistor T2b′ and the first light emitting element LEDa′ may be secured. In addition, a separation distance in a plan view between the second transistor T2b′ and the third light emitting element LEDc′ may be secured. Accordingly, light emitted from the first light emitting element LEDa′ and the third light emitting element LEDc′ may be prevented from reaching the second transistor T2b′. Accordingly, deterioration of the second transistor T2b′ may be prevented or reduced. In addition, a separation distance in a plan view between the second transistor T2c′ and the second light emitting element LEDb′ may be secured. Accordingly, light emitted from the second light emitting element LEDb′ may be prevented from reaching the second transistor T2c′. Accordingly, deterioration of the second transistor T2c′ may be prevented or reduced.

The display device (e.g., the display device DD of FIG. 1) according to one or more embodiments may be applied to various electronic devices. An electronic device according to one or more embodiments may include the above-described display device, and may further include a module or device having other additional functions in addition to the display device.

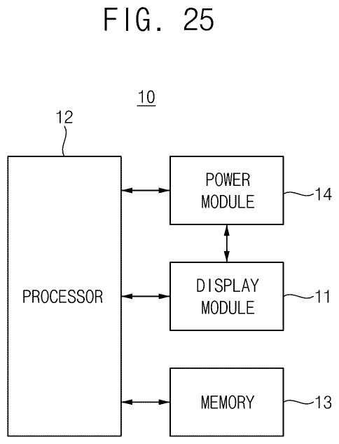

FIG. 25 is a block diagram illustrating an electronic device according to one or more embodiments.

Referring to FIG. 25, an electronic device 10 according to one or more embodiments may include a display module 11, a processor 12, a memory 13, and a power module 14.

The processor 12 may include a central processing unit (“CPU”), an application processor (“AP”), a graphic processing unit (“GPU”), a communication processor (“CP”), an image signal processor (“ISP”), and/or a controller.

Data information necessary for operation of the processor 12 or the display module 11 may be stored in the memory 15. When the processor 12 executes an application stored in the memory 15, an image data signal and/or an input control signal is transmitted to the display module 11, and the display module 11 may process received signal and output image information through a display screen.

The power module 14 may include a power supply module such as a power adapter and/or a battery device, and a power conversion module that converts power supplied by the power supply module to generate power required for operation of the electronic device 10.

At least one of the components of the electronic device 10 described above may be included in the display device according to the above-described embodiments. In addition, some of individual modules functionally included in one module may be included in the display device, and others may be provided separately from the display device. For example, the display device may include the display module 11, and the processor 12, the memory 13, and the power module 14 may be provided in form of another device in the electronic device 10 other than the display device.

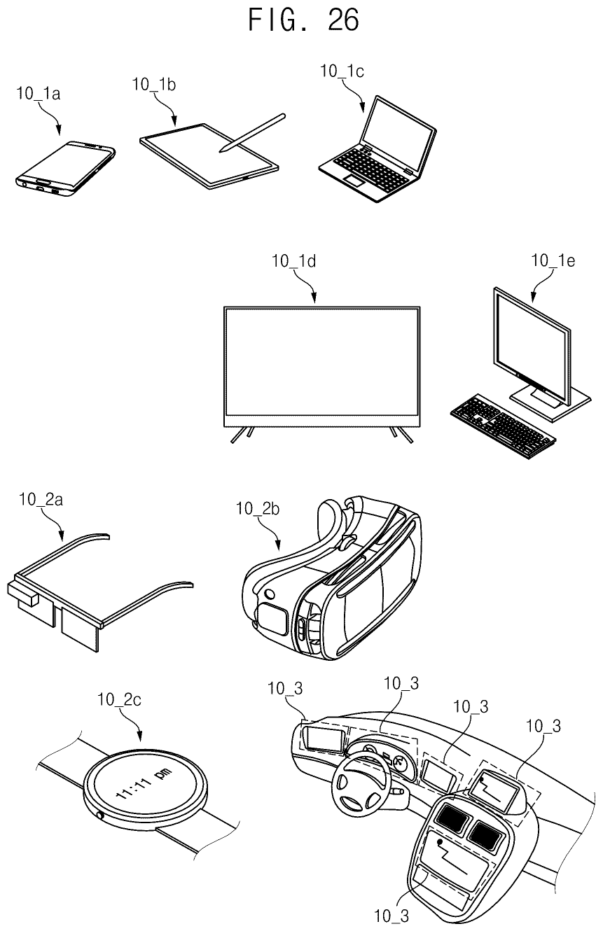

FIG. 26 is a schematic diagram of an electronic device according to one or more embodiments.

Referring to FIG. 26, various electronic devices to which display devices according to one or more embodiments are applied may include not only electronic devices for image display such as a smartphone 10_1a, a tablet PC 10_1b, a laptop 10_1c, a TV 10_1d, a desk monitor 10_1e, and/or the like, but wearable electronic devices including display modules such as a smart glass 10_2a, a head mounted display 10_2b, a smart watch 10_2c, and/or the like, vehicle electronic device 10_3 including display modules such as a vehicle's instrument panel, a center fascia, a center information display (“CID”) located on a dashboard, a room mirror display, and/or the like.

The foregoing is illustrative of embodiments and is not to be construed as limiting thereof. Although a few embodiments have been described, those skilled in the art will readily appreciate that many modifications are possible in the embodiments without materially departing from the novel teachings and scope of the present disclosure. Accordingly, all such modifications are intended to be included within the scope of the present disclosure as defined in the claims and their equivalents. Therefore, it is to be understood that the foregoing is illustrative of various embodiments and is not to be construed as limited to the specific embodiments disclosed, and that modifications to the embodiments, as well as other embodiments, are intended to be included within the scope of the appended claims and their equivalents.

What is claimed is:

1. A display device comprising:
a first light emitting element;
a second light emitting element spaced from the first light emitting element in a plan view;
a first pixel driving circuit portion comprising a driving transistor electrically connected to the first light emitting element, wherein the driving transistor in the first pixel driving circuit portion at least partially overlaps the first light emitting element in a plan view; and
a second pixel driving circuit portion comprising a driving transistor electrically connected to the second light emitting element, wherein the driving transistor in the second pixel driving circuit portion at least partially overlaps the first light emitting element in a plan view.

2. The display device of claim 1, wherein:
the driving transistor in the first pixel driving circuit portion is configured to provide a driving current to the first light emitting element; and
the driving transistor in the second pixel driving circuit portion is configured to provide a driving current to the second light emitting element.

3. The display device of claim 1, further comprising:
a voltage line electrically connected to each of the first pixel driving circuit portion and the second pixel driving circuit portion.

4. The display device of claim 3, wherein the driving transistor in the first pixel driving circuit portion is located at one side of the voltage line, and
wherein the driving transistor in the second pixel driving circuit portion is located at other side of the voltage line.

5. The display device of claim 3, wherein each of the first pixel driving circuit portion and the second pixel driving circuit portion further comprises a capacitor,
wherein the capacitor in the first pixel driving circuit portion is located at one side of the voltage line, and
wherein the capacitor in the second pixel driving circuit portion is located at an other side of the voltage line.

6. The display device of claim 3, wherein the voltage line is configured to apply a power voltage to each of the first pixel driving circuit portion and the second pixel driving circuit portion.

7. The display device of claim 3, wherein each of the first pixel driving circuit portion and the second pixel driving circuit portion further comprises a first switching transistor,
wherein the first switching transistor in the first pixel driving circuit portion is located at one side of the voltage line, and
wherein the first switching transistor in the second pixel driving circuit portion is located at an other side of the voltage line.

8. The display device of claim 7, wherein each of the first pixel driving circuit portion and the second pixel driving circuit portion further comprises a second switching transistor, and
wherein each of the second switching transistor in the first pixel driving circuit portion and the second switching transistor in the second pixel driving circuit portion is located at the one side of the voltage line or the other side of the voltage line.

9. The display device of claim 1, further comprising:
a third light emitting element spaced from each of the first light emitting element and the second light emitting element in a plan view; and
a third pixel driving circuit portion comprising a driving transistor electrically connected to the third light emitting element,
wherein the driving transistor in the third pixel driving circuit portion at least partially overlaps the third light emitting element in a plan view.

10. The display device of claim 9, wherein the first light emitting element, the second light emitting element, and the third light emitting element are configured to emit light having different wavelengths from each other.

11. The display device of claim 9, further comprising:
a voltage line electrically connected to each of the first pixel driving circuit portion, the second pixel driving circuit portion, and the third pixel driving circuit portion.

12. The display device of claim 11, wherein each of the driving transistor in the first pixel driving circuit portion and the driving transistor in the third pixel driving circuit portion is located at one side of the voltage line, and
wherein the driving transistor in the second pixel driving circuit portion is located at an other side of the voltage line.

13. The display device of claim 11, wherein each of the first pixel driving circuit portion, the second pixel driving circuit portion, and the third pixel driving circuit portion further comprises a capacitor,
wherein each of the capacitor in the first pixel driving circuit portion and the capacitor in the third pixel driving circuit portion is located at one side of the voltage line, and
wherein the capacitor in the second pixel driving circuit portion is located at an other side of the voltage line.

14. A display device comprising:
a first light emitting element;
a second light emitting element spaced from the first light emitting element in a plan view;
a voltage line;
a first pixel driving circuit portion comprising a driving transistor located at one side of the voltage line, wherein the first pixel driving circuit portion is electrically connected to each of the first light emitting element and the voltage line; and
a second pixel driving circuit portion comprising a driving transistor located at an other side of the voltage line, wherein the second pixel driving circuit portion is electrically connected to each of the second light emitting element and the voltage line.

15. The display device of claim 14, wherein the driving transistor in the first pixel driving circuit portion at least partially overlaps the first light emitting element in a plan view, and
wherein the driving transistor in the second pixel driving circuit portion at least partially overlaps the second light emitting element in a plan view.

16. The display device of claim 14, wherein the voltage line is configured to apply a power voltage to each of the first pixel driving circuit portion and the second pixel driving circuit portion.

17. The display device of claim 14, wherein each of the first pixel driving circuit portion and the second pixel driving circuit portion further comprises a capacitor,
wherein the capacitor in the first pixel driving circuit portion is located at the one side of the voltage line, and
wherein the capacitor in the second pixel driving circuit portion is located at the other side of the voltage line.

18. The display device of claim 14, further comprising:
a third light emitting element spaced from each of the first light emitting element and the second light emitting element in a plan view; and
a third pixel driving circuit portion electrically connected to each of the third light emitting element and the voltage line.

19. The display device of claim 18, wherein the third pixel driving circuit portion comprises a driving transistor located at the one side of the voltage line or the other side of the voltage line.

20. An electronic device comprising:
a first light emitting element;
a second light emitting element spaced from the first light emitting element in a plan view;
a first pixel driving circuit portion comprising a driving transistor electrically connected to the first light emitting element, wherein the driving transistor in the first pixel driving circuit portion at least partially overlaps the first light emitting element in a plan view;
a second pixel driving circuit portion comprising a driving transistor electrically connected to the second light emitting element, wherein the driving transistor in the second pixel driving circuit portion at least partially overlaps the first light emitting element in a plan view; and
a memory configured to store data information.
